(19) United States
(12) Patent Application Publication
(10) Pub. No.: US 2026/0085233 A1
(43) Pub. Date: Mar. 26, 2026

(54) PYRROMETHENE-BORON COMPLEX, COLOR CONVERSION COMPOSITION, COLOR CONVERSION SHEET, COLOR CONVERSION SUBSTRATE, LIGHT SOURCE UNIT, DISPLAY DEVICE, AND LIGHTING DEVICE

(71) Applicant: Toray Industries, Inc., Chuo-ku, Tokyo (JP)

(72) Inventors: Motonobu ICHIKAWA, Otsu-shi, Shiga (JP); Yasunori ICHIHASHI, Otsu-shi, Shiga (JP); Tsubasa OKANO, Kamakura-shi, Kanagawa (JP); Juhee CHOI, Seoul (KR)

(73) Assignee: Toray Industries, Inc., Chuo-ku, Tokyo (JP)

(21) Appl. No.: 19/111,171

(22) PCT Filed: Sep. 29, 2023
(86) PCT No.: PCT/JP2023/035666

§ 371 Date: Mar. 12, 2025

(30) Foreign Application Priority Data
Oct. 7, 2022 (JP) 2022-162078

(51) Int. Cl. C09K 11/06; C07F 5/02; G02F 1/13357; H10H 29/851

(52) U.S. Cl. CPC C09K 11/06; C07F 5/027; G02F 1/133617; C09K 2211/1007; C09K 2211/1011; C09K 2211/1018; C09K 2211/188; H10H 29/8512

(57) ABSTRACT

Provided is a pyrromethene-boron complex having the following general formula (1):

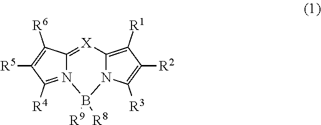

wherein X is C—R⁷ and R¹ to R⁹ are as defined, wherein one of two pairs: R⁴ and R⁵, and R⁵ and R⁶, has a ring structure of any one of the following general formulas (2A) to (2D):

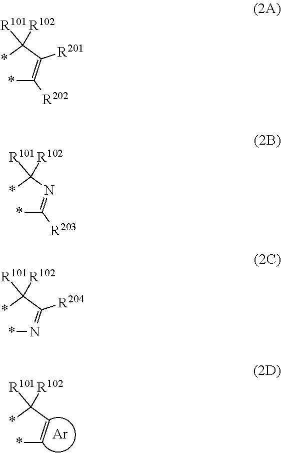

wherein in the general formulas (2A) to (2D), R¹⁰¹, R¹⁰² and R²⁰¹ to R²⁰⁴ are the same as R² and R⁴ to R⁹ in the general formula (1); Ar is a substituted or unsubstituted aromatic hydrocarbon ring, or a substituted or unsubstituted aromatic heterocycle; R¹⁰¹ and R¹⁰² may form a ring; and the symbol * indicates a connection with the pyrromethene skeleton.

### CROSS REFERENCE TO RELATED APPLICATIONS

This application is the U.S. National Phase of PCT/JP2023/035666, filed Sep. 29, 2023, which claims priority to Japanese Patent Application No. 2022-162078, filed Oct. 7, 2022, the disclosures of these applications being incorporated herein by reference in their entireties for all purposes.

### FIELD OF THE INVENTION

The present invention relates to a pyrromethene-boron complex, a color conversion composition, a color conversion sheet, a color conversion substrate, a light source unit, a display device, and a lighting device.

### BACKGROUND OF THE INVENTION

There are many studies on the application of multi-color technology based on color conversion systems to liquid crystal displays, organic EL displays, lighting devices, and the like. Color conversion represents to convert a light emitted from a light emitter into a light having a longer wavelength. Examples of the color conversion include converting blue emission into green or red emission.

A composition having a color conversion function (hereinafter referred to as a color conversion composition) is formed into a sheet and combined, for example, with a blue light source, and three primary colors of blue, green, and red can thereby be obtained from the blue light source, i.e., white light can be obtained. Such a white light source formed by combining a blue light source and a sheet having a color conversion function (hereinafter referred to as a color conversion sheet) can be used as a light source unit such as a backlight unit, and the light source unit can be combined with a liquid crystal driver and a color filter to produce a full-color display. Further, the white light source obtained by combining a blue light source with a color conversion sheet can be used as a white light source such as a LED lighting as it is.

The problem to be solved in a display device, such as a liquid crystal display, utilizing a color conversion system includes improvement of color reproducibility. High color purity of blue, green, and red, achieved by reducing the half-value width of the emission spectrum of a light source unit with respect to blue, green, and red light, is effective in improving color reproducibility. As a means to solve this task, for example, techniques using pyrromethene compounds as components of the color conversion composition have been proposed (see, for example, Patent Literatures 1 and 2). Further, as a technique to further enhance the color purity, a compound in which a fused ring structure is introduced into a pyrromethene skeleton has been known (see, for example, Patent Literature 3).

### PATENT LITERATURE

Patent Literature 1: JP 2010-61824 A
Patent Literature 2: JP 2014-136771 A
Patent Literature 3: WO 2020/045242

### SUMMARY OF THE INVENTION

However, it was found that the techniques described in Patent Literatures 1 to 3 have a problem in that the fluorescence quantum yield is insufficient.

The present invention has been made in view of the above circumstances, and a first object of the present invention is to provide a pyrromethene-boron complex which is excellent in color purity and can provide a high fluorescence quantum yield. A second object of present invention is to provide a pyrromethene-boron complex, a color conversion composition, a color conversion sheet, a color conversion substrate, a light source unit, a display device, and a lighting device.

In order to solve the above problem and achieve the object, the present invention has a constitution described in any one of [1] to below.

That is,
[1] The pyrromethene-boron complex according to the present invention is a compound of the following general formula (1):

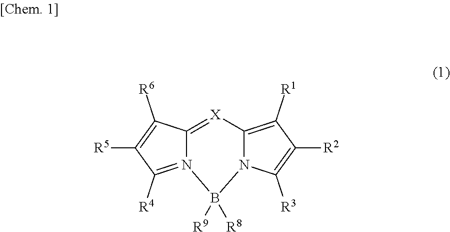

(wherein in the general formula (1), X is C—R⁷ or N;
R¹ and R³ are aryl groups which are different from each other;
each of R² and R⁴ to R⁹, which may be the same as or different from one another, is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group;
provided that one of two pairs: R⁴ and R⁵, and R⁵ and R⁶, has a ring structure of any one of the following general formulas (2A) to (2D):

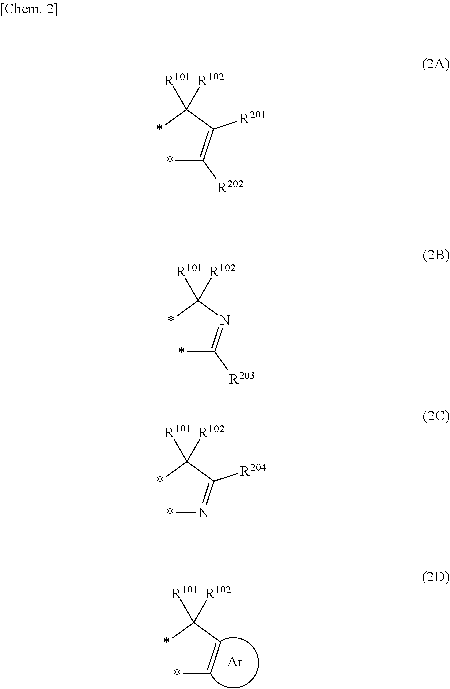

(wherein in the general formulas (2A) to (2D), R¹⁰¹, R¹⁰² and R²⁰¹ to R²⁰⁴ are the same as R² and R⁴ to R⁹ in the general formula (1);
Ar is a substituted or unsubstituted aromatic hydrocarbon ring, or a substituted or unsubstituted aromatic heterocycle;
R¹⁰¹ and R¹⁰² may form a ring; and
the symbol * indicates a connection with the pyrromethene skeleton)).
[2] In the pyrromethene-boron complex according to the present invention described above in [1], the compound of the general formula (1) is a compound of any one of the following general formulas (3A) to (3D):

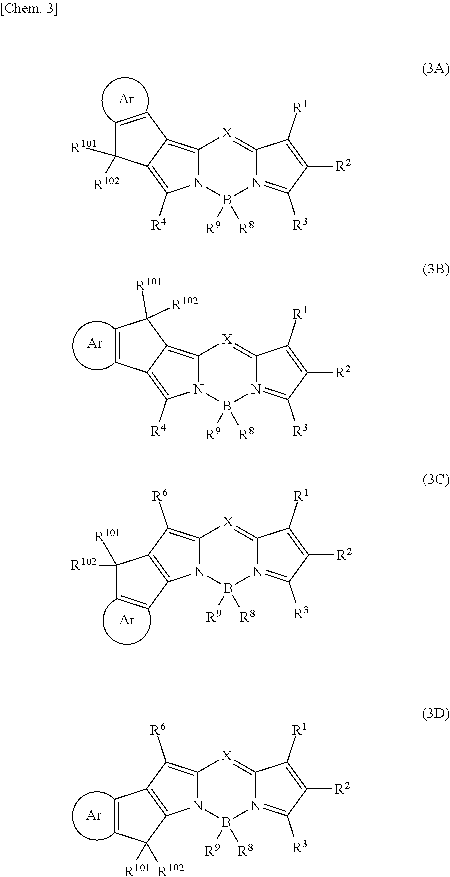

(wherein in the general formulas (3A) to (3D), R¹⁰¹ and R¹⁰² are the same as R², and R⁴ to
R⁹ in said general formula (1);
Ar is a substituted or unsubstituted aromatic hydrocarbon ring, or a substituted or unsubstituted aromatic heterocycle; and
R¹⁰¹ and R¹⁰² may form a ring).
[3] In the pyrromethene-boron complex according to the present invention described above in [1] or [2], the Ar is a substituted or unsubstituted benzene ring.
[4] In the pyrromethene-boron complex according to the present invention described above in any one of [1] to [3], in the general formula (1), R¹ and R³ are substituted or unsubstituted phenyl groups which are different from each other.
[5] In the pyrromethene-boron complex according to the present invention described above in any one of [1] to [4], in the general formula (1), R¹ is a phenyl group having a substituent in the ortho position.
[6] In the pyrromethene-boron complex according to the present invention described above in any one of [1] to [5], in the general formulas (1), and (2A) to (2D), at least one of R¹ to R³, R¹⁰¹, R¹⁰², R²⁰¹ to R²⁰⁴, and Ar is a group containing an electron withdrawing group.
[7] In the pyrromethene-boron complex according to the present invention described above in any one of [1] to [6], in the general formula (1), at least one of R¹ to R³ is a group containing an electron withdrawing group.
[8] In the pyrromethene-boron complex according to the present invention described above in any one of [1] to [7], the electron withdrawing group is fluorine, a fluorine-containing aryl group, a fluorine-containing heteroaryl group, a fluorine-containing alkyl group, a substituted or unsubstituted acyl group, a substituted or unsubstituted ester group, a substituted or unsubstituted amide group, a substituted or unsubstituted sulfonyl group, or a cyano group.
[9] In the pyrromethene-boron complex according to the present invention described above in any one of [1] to [8], in the general formula (1), X is C—R⁷, and R⁷ is a group of the following general formula (4):

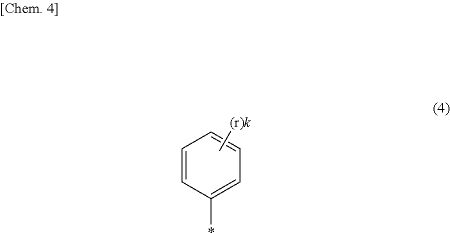

(wherein in the general formula (4), r is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group; k is an integer of 1 to 3; and when k is 2 or more, r may be the same as or different from one another).
[10] In the pyrromethene-boron complex according to the present invention described above in any one of [1] to [9], the compound of the general formula (1) emits light observed in a region having a peak wavelength of 580 nm to 750 nm when excitation light is used.
[11] A color conversion composition according to the present invention is a color conversion composition that converts an incident light into a light with a wavelength longer than that of the incident light, and includes the pyrromethene-boron complex described above in any one of [1] to [10]; and a binder resin.
[12] A color conversion sheet according to the present invention includes a color conversion layer composed of the color conversion composition described above in or a cured product thereof.
[13] A color conversion substrate according to the present invention includes a plurality of color conversion layers on a transparent substrate, wherein the plurality of color conversion layers are composed of the color conversion composition described above in or a cured product thereof.
[14] A light source unit according to the present invention includes: a light source, and the color conversion sheet described above in or the color conversion substrate described above in [13].
[15] In the light source unit according to the present invention described above in [14], the light source is a light-emitting diode having a maximum light emission in the wavelength range of 430 nm to 500 nm.
[16] A display device according to the present invention includes the color conversion sheet described above in or the color conversion substrate described above in [13].
[17] A lighting device according to the present invention includes the color conversion sheet described above in or the color conversion substrate described above in [13].

The present invention is effective in providing a pyrromethene-boron complex which is excellent in color purity and can provide a high fluorescence quantum yield.

The pyrromethene-boron complex can provide a color conversion composition, a color conversion sheet, and a color conversion substrate capable of obtaining light emission with high fluorescence quantum yield and high color purity (for example, red emission), and is effective in improving the color reproducibility of light source units, display devices such as liquid crystal displays, and lighting devices.

### BRIEF DESCRIPTION OF THE DRAWINGS

FIG. 1 is a schematic cross-sectional view depicting the first example of a color conversion sheet according to an embodiment of the present invention.

FIG. 2 is a schematic cross-sectional view depicting the second example of a color conversion sheet according to an embodiment of the present invention.

FIG. 3 is a schematic cross-sectional view depicting the third example of a color conversion sheet according to an embodiment of the present invention.

FIG. 4 is a schematic cross-sectional view depicting the fourth example of a color conversion sheet according to an embodiment of the present invention.

### DETAILED DESCRIPTION OF EMBODIMENTS OF THE INVENTION

Suitable embodiments of the pyrromethene-boron complex according to the present invention, and the color conversion composition, the color conversion sheet, color conversion substrate, light source unit, display device, and lighting device using the pyrromethene-boron complex according to the present invention will be specifically described below, but the present invention is not limited to the following embodiments and can be modified in various ways depending on the purpose and application.

### (Pyrromethene-Boron Complex)

The pyrromethene-boron complex according to the embodiment of the present invention (hereinafter, sometimes abbreviated as the pyrromethene-boron complex of the present invention) will be described in detail. The pyrromethene-boron complex of the present invention is a compound of the following general formula (1):

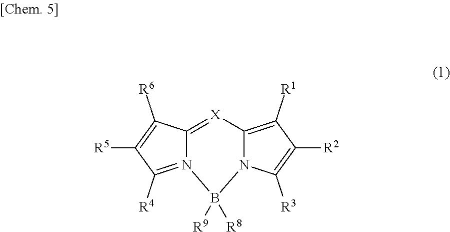

In the general formula (1), X is C—R⁷ or N. R¹ and R³ are aryl groups which are different from each other. Each of R² and R⁴ to R⁹, which may be the same as or different from one another, is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group, provided that one of two pairs: R⁴ and R⁵, and R⁵ and R⁶, has a ring structure of any one of the following general formulas (2A) to (2D):

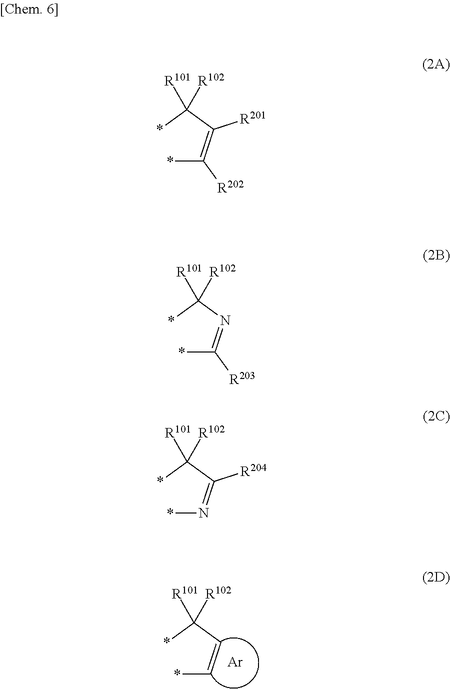

In the general formulas (2A) to (2D), R¹⁰¹, R¹⁰² and R²⁰¹ to R²⁰⁴ are the same as R² and R⁴ to R⁹ in the general formula (1). Ar is a substituted or unsubstituted aromatic hydrocarbon ring, or a substituted or unsubstituted aromatic heterocycle. R¹⁰¹ and R¹⁰² may form a ring. In each ring structure of each of the general formulas (2A) to (2D), the symbol * indicates a connection with the pyrromethene skeleton.

In all of the groups described above, hydrogen may be deuterium. This also applies to the compounds or their partial structures described below. In the following description, for example, a substituted or unsubstituted aryl group having a carbon number of 6 to 40 means that the number of all carbons is from 6 to 40 including the number of carbons contained in a substituent substituted on the aryl group, and the same applies to other substituents of which carbon number is specified.

In all the groups described above, preferred examples of the substituents in the case of substitution include alkyl groups, cycloalkyl groups, heterocyclic groups, alkenyl groups, cycloalkenyl groups, alkynyl groups, hydroxyl groups, thiol groups, alkoxy groups, alkylthio groups, aryl ether groups, aryl thioether groups, aryl groups, heteroaryl groups, halogens, cyano groups, aldehyde groups, carbonyl groups, carboxyl groups, oxycarbonyl groups, carbamoyl groups, amino groups, nitro groups, silyl groups, siloxanyl groups, boryl groups, and phosphine oxide groups. Furthermore, a specific substituent which is explained to be preferred in the description of each substituent is preferred. These substituents may further be substituted with the above-described substituent.

The term “unsubstituted” in “substituted or unsubstituted” means the substitution with a hydrogen atom or a deuterium atom. The same definition applies to “substituted or unsubstituted” in the compounds or their partial structures described below.

Of all the groups described above, the alkyl group refers to, for example, a saturated aliphatic hydrocarbon group such as a methyl group, an ethyl group, an n-propyl group, an isopropyl group, an n-butyl group, a sec-butyl group, or a tert-butyl group, which may or may not have a substituent. In the case of the substitution, an additional substituent is subject to no particular limitation, and examples of substituents include an alkyl group, halogen, an aryl group, a heteroaryl group, and the like. The same applies below. The carbon number of the alkyl group is not particularly limited but in view of easy availability and cost, is preferably 1 or more and 20 or less, and more preferably 1 or more and 8 or less.

The cycloalkyl group refers to, for example, a saturated alicyclic hydrocarbon group such as a cyclopropyl group, a cyclohexyl group, a norbornyl group, and an adamantyl group, which may or may not have a substituent. The carbon number of the alkyl group moiety is not particularly limited, but is preferably in the range of 3 or more and 20 or less.

The heterocyclic group refers to, for example, an aliphatic ring having an atom other than carbon in the ring, such as pyrane ring, piperidine ring and cyclic amide, which may or may not have a substituent. The carbon number of the heterocyclic group is not particularly limited, but is preferably in the range of 2 or more and 20 or less.

The alkenyl group refers to, for example, an unsaturated aliphatic hydrocarbon group containing a double bond, such as a vinyl group, an allyl group, or a butadienyl group, which may or may not have a substituent. The carbon number of the alkenyl group is not particularly limited, but is preferably in the range of 2 or more and 20 or less.

The cycloalkenyl group refers to, for example, an unsaturated alicyclic hydrocarbon group containing a double bond, such as a cyclopentenyl group, a cyclopentadienyl group, a cyclohexenyl group, which may or may not have a substituent. The carbon number of the cycloalkenyl group is not particularly limited but is preferably in the range of 3 or more and 20 or less.

The alkynyl group refers to, for example, an unsaturated aliphatic hydrocarbon group containing a triple bond, such as an ethynyl group, which may or may not have a substituent. The carbon number of the alkynyl group is not particularly limited, but is preferably in the range of 2 or more and 20 or less.

The alkoxy group refers to, for example, a functional group in which an aliphatic hydrocarbon group is bound via an ether bond, such as a methoxy group, an ethoxy group, or a propoxy group, and the aliphatic hydrocarbon group may or may not have a substituent. The carbon number of the alkoxy group is not particularly limited, but is preferably in the range of 1 or more and 20 or less.

The alkylthio group is an alkoxy group in which the oxygen atom of the ether bond is substituted with a sulfur atom. The hydrocarbon group of the alkylthio group may or may not have a substituent. The carbon number of the alkylthio group is not particularly limited, but is preferably in the range of 1 or more and 20 or less.

The aryl ether group refers to, for example, a functional group to which an aromatic hydrocarbon group is bonded through an ether bond, such as phenoxy group, and the aromatic hydrocarbon group may or may not have a substituent. The carbon number of the aryl ether group is not particularly limited, but is preferably in the range of 6 or more and 40 or less.

The aryl thioether group refers to an aryl ether group in which the oxygen atom of the ether bond is substituted with a sulfur atom. The aromatic hydrocarbon group in the aryl thioether group may or may not have a substituent. The carbon number of the aryl thioether group is not particularly limited, but is preferably in the range of 6 or more and 40 or less.

The aryl group refers to, for example, an aromatic hydrocarbon group such as a phenyl group, a biphenyl group, a terphenyl group, a naphthyl group, a fluorenyl group, a benzofluorenyl group, a dibenzofluorenyl group, a phenanthryl group, an anthracenyl group, a benzophenanthryl group, a benzoanthracenyl group, a chrysenyl group, a pyrenyl group, a fluoranthenyl group, a triphenylenyl group, a benzofluoranthenyl group, a dibenzoanthracenyl group, a perylenyl group and a helicenyl group. Among them, a phenyl group, a biphenyl group, a terphenyl group, a naphthyl group, a fluorenyl group, a phenanthryl group, an anthracenyl group, a pyrenyl group, a fluoranthenyl group, and a triphenylenyl group are preferred. The aryl group may or may not have a substituent. The carbon number of the aryl group is not particularly limited, but is preferably in the range of 6 or more and 40 or less, and more preferably 6 or more and 30 or less. When R², and R⁴ to R⁹ in the general formula (1) are substituted or unsubstituted aryl groups, the aryl group is preferably a phenyl group, a biphenyl group, a terphenyl group, a naphthyl group, a fluorenyl group, a phenanthryl group, or an anthracenyl group, and more preferably a phenyl group, a biphenyl group, a terphenyl group, or a naphthyl group. A phenyl group, a biphenyl group, or a terphenyl group is still more preferred, and a phenyl group is particularly preferred.

When each substituent is further substituted with an aryl group, the aryl group is preferably a phenyl group, a biphenyl group, a terphenyl group, a naphthyl group, a fluorenyl group, a phenanthryl group, or an anthracenyl group, and more preferably a phenyl group, a biphenyl group, a terphenyl group, or a naphthyl group. A phenyl group is particularly preferred.

The heteroaryl group refers to, for example, a cyclic aromatic group having one or more atoms other than carbon in the ring, such as a pyridyl group, a furanyl group, a thienyl group, a quinolinyl group, an isoquinolinyl group, a pyrazinyl group, a pyrimidyl group, a pyridazinyl group, a triazinyl group, a naphthyridinyl group, a cinnolinyl group, a phthalazinyl group, a quinoxalinyl group, a quinazolinyl group, a benzofuranyl group, a benzothienyl group, an indolyl group, a dibenzofuranyl group, a dibenzothienyl group, a carbazolyl group, a benzocarbazolyl group, a carbolinyl group, an indolocarbazolyl group, a benzofurocarbazolyl group, a benzothienocarbazolyl group, dihydroindenocarbazolyl group, benzoquinolinyl group, an acridinyl group, a dibenzoacridinyl group, a benzimidazolyl group, an imidazopyridyl group, a benzoxazolyl group, a benzothiazolyl group, or a phenanthrolinyl group. The naphthyridinyl group refers to any of a 1,5-naphthyridinyl group, a 1,6-naphthyridinyl group, a 1,7-naphthyridinyl group, a 1,8-naphthyridinyl group, a 2,6-naphthyridinyl group and a 2,7-naphthyridinyl group. The heteroaryl group may or may not have a substituent. The carbon number of the heteroaryl group is not particularly limited, but is preferably in the range of 2 or more and 40 or less, and more preferably 2 or more and 30 or less.

In the case where R², and R⁴ to R⁹ in the general formula (1) are a substituted or unsubstituted heteroaryl group, the heteroaryl group is preferably a pyridyl group, a furanyl group, a thienyl group, a quinolinyl group, a pyrimidyl group, a triazinyl group, a benzofuranyl group, a benzothienyl group, an indolyl group, a dibenzofuranyl group, a dibenzothienyl group, a carbazolyl group, a benzimidazolyl group, an imidazopyridyl group, a benzoxazolyl group, a benzothiazolyl group, or a phenanthrolinyl group, more preferably a pyridyl group, a furanyl group, a thioenyl group, or a quinolinyl group, and particularly preferably a pyridyl group.

In the case where each substituent is further substituted with a heteroaryl group, the heteroaryl group is preferably a pyridyl group, a furanyl group, a thienyl group, a quinolinyl group, a pyrimidyl group, a triazinyl group, a benzofuranyl group, a benzothienyl group, an indolyl group, a dibenzofuranyl group, a dibenzothienyl group, a carbazolyl group, a benzimidazolyl group, an imidazopyridyl group, a benzoxazolyl group, a benzothiazolyl group, or a phenanthrolinyl group, more preferably a pyridyl group, a furanyl group, a thienyl group, or a quinolinyl group, and particularly preferably a pyridyl group.

Halogen refers to an atom selected from fluorine, chlorine, bromine and iodine. The carbonyl group, carboxyl group, oxycarbonyl group and carbamoyl group may or may not have a substituent. Here, examples of substituents include an alkyl group, a cycloalkyl group, an aryl group, a heteroaryl group, and the like, and the substituent may be further substituted.

The amino group is a substituted or unsubstituted amino group. The amino group may or may not have a substituent, and when the amino group is substituted, the substituent is, for example, an aryl group, a heteroaryl group, a linear alkyl group, or a branched alkyl group. As the aryl group or the heteroaryl group, a phenyl group, a naphthyl group, a pyridyl group or a quinolinyl group is preferred. These substituents may be further substituted. The carbon number is not particularly limited, but is preferably in the range of 2 or more and 50 or less, more preferably 6 or more and 40 or less, and particularly preferably 6 or more and 30 or less.

The silyl group refers to, for example, an alkylsilyl group such as a trimethylsilyl group, a triethylsilyl group, a tert-butyldimethylsilyl group, a propyldimethylsilyl group and a vinyldimethylsilyl group, or an arylsilyl group such as a phenyldimethylsilyl group, a tert-butyldiphenylsilyl group, a triphenylsilyl group or a trinaphthylsilyl group. The substituent on the silicon atom may be further substituted. The carbon number of the silyl group is not particularly limited, but is preferably in the range of 1 or more and 30 or less.

The siloxanyl group refers to, for example, a silicon compound group via an ether bond, such as trimethylsiloxanyl group. The substituent on the silicon atom may be further substituted. The boryl group refers to a substituted or unsubstituted boryl group. The boryl group may or may not have a substituent, and in a case where the boryl group is substituted, the substituent is, for example, an aryl group, a heteroaryl group, a linear alkyl group, a branched alkyl group, an aryl ether group, an alkoxy group, or a hydroxyl group, and among them, aryl groups and aryl ether groups are preferred. In addition, the phosphine oxide group is a group represented by —P(═O) R¹⁰R¹¹. R¹⁰ and R¹¹ in a phosphine oxide group are selected from the same group as those for R², and R⁴ to R⁹ in the general formula (1).

The compound of the general formula (1) has a pyrromethene-boron complex skeleton. The pyrromethene-boron complex skeleton is a strong skeleton with a high planarity. Therefore, a compound of the general formula (1) having the pyrromethene-boron complex skeleton exhibits a high fluorescence quantum yield. Furthermore, the compound of the general formula (1) provides an emission spectrum with the peak half-value width being small, so that efficient light emission, that is, improved fluorescence quantum yield and high color purity can be achieved.

In general, when a pyrromethene-boron complex is used to emit light in a wavelength region longer than that of green, the pyrromethene-boron complex extends the conjugation and lengthen the wavelength of emission by directly bonding a group having a double bond to the pyrromethene-boron complex skeleton. However, if the group having a double bond is simply bound to the pyrromethene-boron complex skeleton, the pyrromethene-boron complex changes to several stable structures in the excited state thereof (hereinafter, such a phenomenon is referred to as structural relaxation), which results in emission from various energy states, and thus inactivation. In this case, the emission spectrum becomes broad, the half-value width widens, and the color purity decreases. That is, it is necessary to devise a molecular design when the wavelength is lengthened by use of the pyrromethene-boron complex.

The pyrromethene-boron complex of the present invention is a compound of the general formula (1), and has a ring structure of any one of the above general formulas (2A) to (2D) in the pyrromethene-boron complex skeleton. Each ring structure of each of the general formulas (2A) to (2D) has a double bond, and the double bond is always fixed to the pyrromethene-boron complex skeleton with a carbon atom by a chemical bond. As a result, excessive structural relaxation in the excited state can be suppressed, and the emission spectrum of the compound of the general formula (1) becomes sharp. When this compound is used as a luminescent material, emission with good color purity can be obtained. That is, when the compound of the general formula (1) is used in a color conversion composition, larger color gamut can be efficiently created, resulting in improved color reproducibility.

Further, in the pyrromethene-boron complex of the present invention, R¹ and R³ in the general formula (1) are aryl groups which are different from each other. When R¹ and R³ are aryl groups which are different from each other, the dispersibility of the pyrromethene-boron complex is improved, and concentration quenching can be suppressed. For this reason, the fluorescence quantum yield can be improved.

In the present invention, examples of aryl groups which are different from each other include aryl groups having different carbon skeletons such as a phenyl group and a naphthyl group, aryl groups having the same carbon skeleton but different in the presence or absence of substituents or different in types of substituents, such as a phenyl group and a toluyl group, or a t-butylphenyl group and a methoxyphenyl group. When the carbon skeletons of the aryl groups are the same but the substituents are different, the dispersibility of the pyrromethene-boron complex is improved, which is more preferable.

In the compound of the general formula (1), in addition to R¹ and R³ being aryl groups which are different from each other as mentioned above, one of the two pairs: R⁴ and R⁵, and R⁵ and R⁶, is a ring structure of any one of the general formulas (2A) to (2D). Thus, sharp emission can be obtained while the Stokes shift is maintained to some extent. This is because moderate structural relaxation is caused while the compound of the general formula (1) is excited to emit light emission. The Stokes shift is the difference between the absorption maximum wavelength and the fluorescence maximum wavelength.

For the color conversion sheet which converts wavelengths by absorbing a light in a specific wavelength band (for example, excitation light) and emitting a light in a target wavelength band, when there is a large overlap between the absorption spectrum in the specific wavelength band and the emission spectrum in the target wavelength band, re-absorption occurs, in which the emitted light is absorbed again. For this reason, the luminescence efficiency of the color conversion sheet is reduced. Therefore, a large Stokes shift and a small overlap between the above-described absorption spectrum and the above-described emission spectrum are desirable from the viewpoint of luminescence efficiency.

In the pyrromethene-boron complex, excessive suppression of its structural relaxation results in an excessively small Stokes shift, which reduces the luminescence efficiency. Therefore, it is important that when the pyrromethene-boron complex is excited to emit a light, moderate structural relaxation is caused in the pyrromethene-boron complex, in order to achieve high color purity and high luminance. In the compound (pyrromethene-boron complex) of the general formula (1), one of two pairs: R⁴ and R⁵, and R⁵ and R⁶, has a ring structure of any one of the general formulas (2A) to (2D), and R¹ and R³ are aryl groups which are different from each other. As a result, moderate structural relaxation is caused in the process of light emission, and therefore the pyrromethene-boron complex provides an emission spectrum with the peak half-value width being small and has high luminance.

Furthermore, various properties and physical properties such as luminescence efficiency, color purity, thermal stability, light stability and dispersibility can be adjusted by introducing an appropriate substituent into an appropriate position of the compound of the general formula (1).

For example, a compound of the general formula (1) is preferably a compound of any one of the following general formulas (3A) to (3D).

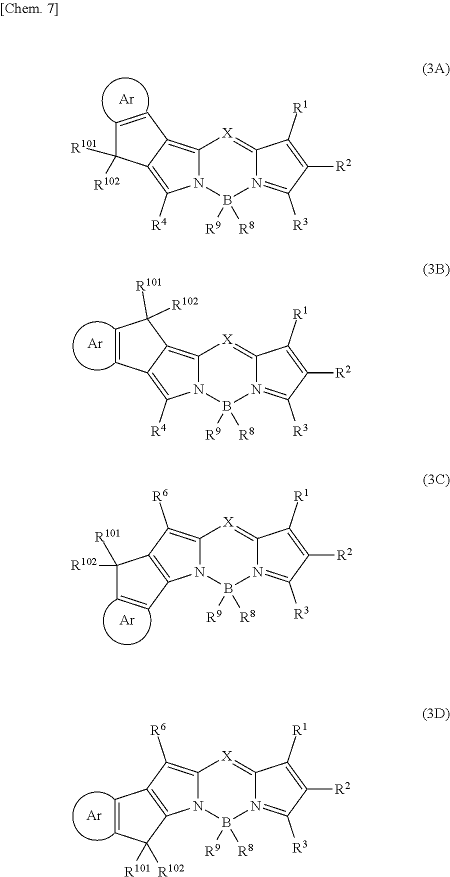

In the general formulas (3A) to (3D), X is C—R⁷ or N. R¹⁰¹ and R¹⁰² are the same as R², and R⁴ to R⁹ in the general formula (1) mentioned above. Ar is a substituted or unsubstituted aromatic hydrocarbon ring, or a substituted or unsubstituted aromatic heterocycle. R¹⁰¹ and R¹⁰² may form a ring.

In each of the compound of the general formula (3A), the compound of the general formula (3B), the compound of the general formula (3C), and the compound of the general formula (3D), the conjugation is efficiently extended, enabling emission with higher color purity at a longer wavelength.

In the general formula (1) (in particular, general formula (2D)) and general formulas (3A) to (3D), Ar is preferably a substituted or unsubstituted benzene ring, a substituted or unsubstituted naphthalene ring, a substituted or unsubstituted phenanthrene ring, a substituted or unsubstituted pyridine ring, a substituted or unsubstituted pyrimidine ring, or a substituted or unsubstituted pyrazine ring. Furthermore, the Ar is particularly preferably a substituted or unsubstituted benzene ring because the thermal and electrical stability improves.

In the pyrromethene-boron complex of the present invention, R¹ and R³ in the general formula (1) are preferably substituted or unsubstituted phenyl groups which are different from each other. This is because with this constitution, the compound of the general formula (1) exhibits better thermal stability and light stability.

In the pyrromethene-boron complex of the present invention, R¹ in the general formula (1) is preferably a phenyl group having a substituent in the ortho position. This is because, when the R¹ is a phenyl group having a substituent in the ortho position, intramolecular rotation in the excited state is suppressed, making it possible to obtain an emission spectrum with a small half-value width. Furthermore, since the R¹ is a phenyl group having a substituent in the ortho position, the dispersibility of the pyrromethene-boron complex is improved, and therefore the fluorescence quantum yield is improved.

Particularly, in the pyrromethene-boron complex of the present invention, R¹ and R³ in the general formula (1) are preferably substituted or unsubstituted aryl groups which are different from each other, and the R¹ is more preferably a phenyl group having a substituent in the ortho position.

In the pyrromethene-boron complex of the present invention, in the general formulas (1), and (2A) to (2D), at least one of R¹ to R³, R¹⁰¹, R¹⁰², R²⁰¹ to R²⁰⁴, and Ar is preferably a group containing an electron withdrawing group. This is because the structural relaxation in the excited state of the compound of the general formula (1) is appropriately caused by the electron withdrawing group, and the Stokes shift becomes larger, thereby further improving the luminescence efficiency. Especially, it is particularly preferable that when at least one of R¹ to R³ is a group containing an electron withdrawing group, the structural relaxation becomes larger.

The electron withdrawing group, otherwise called an electron-accepting group, is, in the organic electron theory, an atomic group that draws electrons by an induction effect or a resonance effect from an atomic group on which the group is substituted. Electron withdrawing groups are substituents with a positive value for the Hammett substituent constant (σp (para)). The Hammett substituent constants (σp (para)) can be obtained from Handbook of Chemistry: Pure Chemistry, revised 5th edition (p. II-380).

Examples of the electron withdrawing group include-F (σp: +0.06), —Cl (σp: +0.23), —Br (σp: +0.23), —I (σp: +0.18), —CO₂R¹² (σp: +0.45 when R¹² is an ethyl group), —CONH₂ (σp: +0.38), —COR¹² (σp: +0.49 when R¹² is a methyl group), —CF₃ (σp: +0.50), —SO₂R¹² (σp: +0.69 when R¹² is a methyl group), and —NO₂ (σp: +0.81). Each R¹² independently represents a hydrogen atom, a substituted or unsubstituted aromatic hydrocarbon group having a ring-forming carbon number of 6 to 30, a substituted or unsubstituted heterocyclic group having a ring-forming carbon number of 5 to 30, a substituted or unsubstituted alkyl group having a carbon number of 1 to 30, or a substituted or unsubstituted cycloalkyl group having a carbon number of 1 to 30. Specific examples of each of these groups are the same as those described above.

The electron withdrawing group is preferably fluorine, a fluorine-containing aryl group, a fluorine-containing heteroaryl group, a fluorine-containing alkyl group, a substituted or unsubstituted acyl group, a substituted or unsubstituted ester group, a substituted or unsubstituted amide group, a substituted or unsubstituted sulfonyl group, or a cyano group, because they are unlikely to be decomposed chemically.

In the pyrromethene-boron complex according to the present invention, in the general formula (1), X is C—R⁷, and this R⁷ is preferably a group of the following general formula (4). This is because it is possible to impart bulkiness to the compound of general formula (1) and thereby improve the luminescence efficiency.

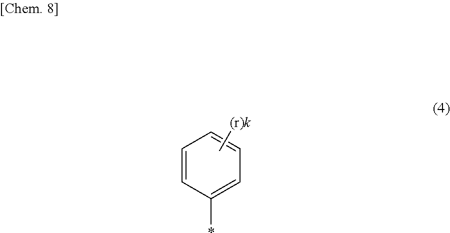

In the general formula (4), r is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group. k is an integer of 1 to 3. When k is 2 or more, r may be the same as or different from one another.

r in the general formula (4) is preferably a substituted or unsubstituted aryl group. Especially among the aryl groups, preferable examples include a phenyl group and a naphthyl group. In the case where the r is an aryl group, k in the general formula (4) is preferably 1 or 2, and more preferably 2. Furthermore, at least one of the r is preferably substituted with an alkyl group or an aryl group. In this case, particularly preferable examples of the alkyl group include a methyl group, an ethyl group, and a tert-butyl group. When the r is an aryl group, a phenyl group or a naphthyl group is preferred as the aryl group. The aryl group may further be substituted with an alkyl group, a heterocyclic group, an alkenyl group, a hydroxyl group, an alkoxy group, an aryl ether group, an aryl group, a heteroaryl group, halogen, a cyano group, a carboxyl group, an ester group, an oxycarbonyl group, or an alkoxy group.

In addition, from the viewpoint of controlling the fluorescence wavelength or absorption wavelength or increasing the compatibility with a solvent, r in the general formula (4) is preferably a substituted or unsubstituted alkyl group, a substituted or unsubstituted alkoxy group, or halogen. Among them, a methyl group, an ethyl group, a tert-butyl group, and a methoxy group are more preferable. In view of dispersibility, a tert-butyl group or a methoxy group is particularly preferred as the r. Thus, quenching due to aggregation of molecules to each other can be prevented.

Examples of the compound of the general formula (1) are illustrated below, but the pyrromethene-boron complex of the present invention is not limited thereto.

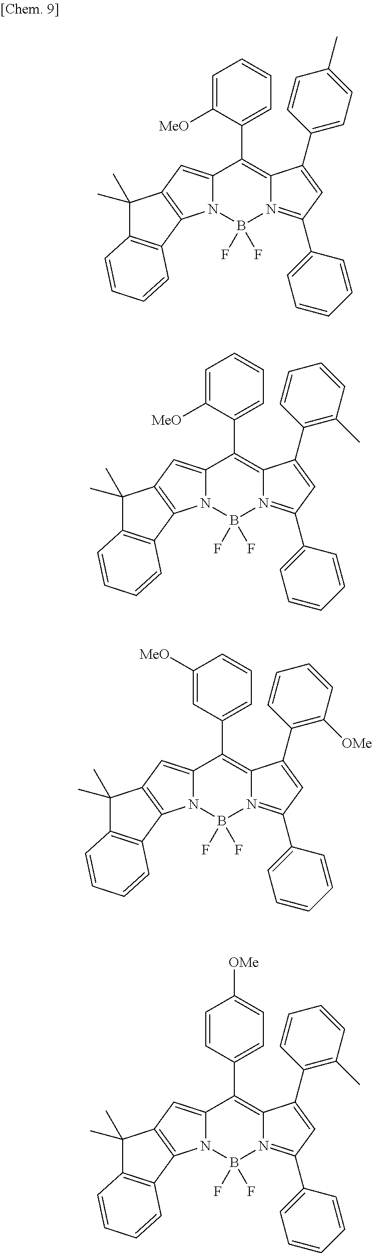

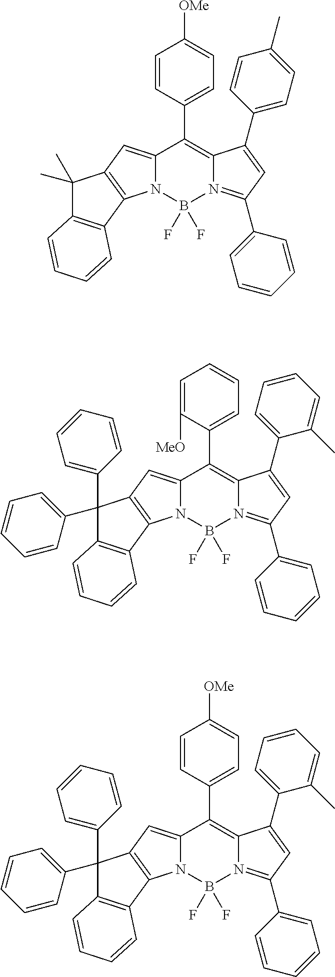

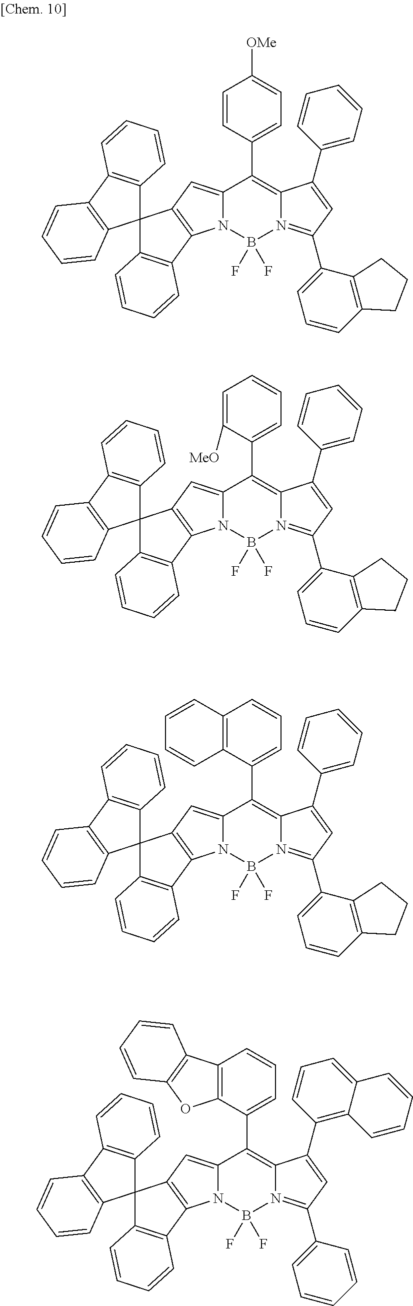

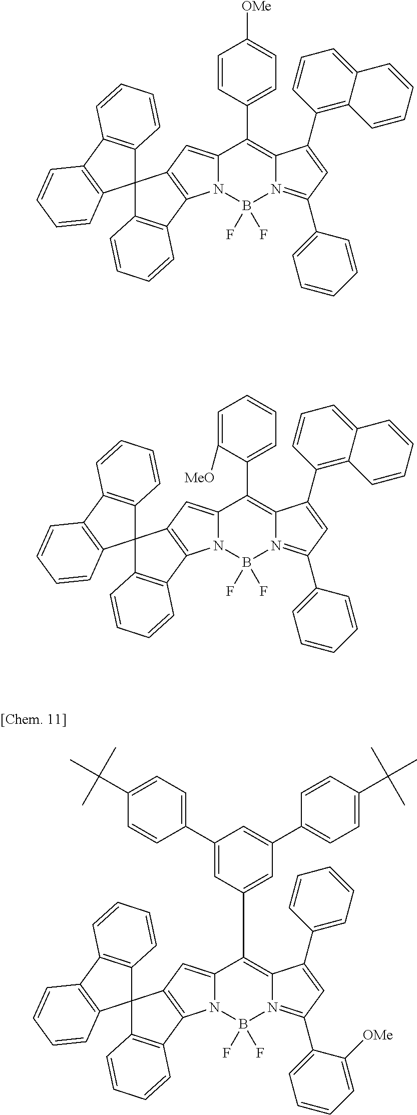

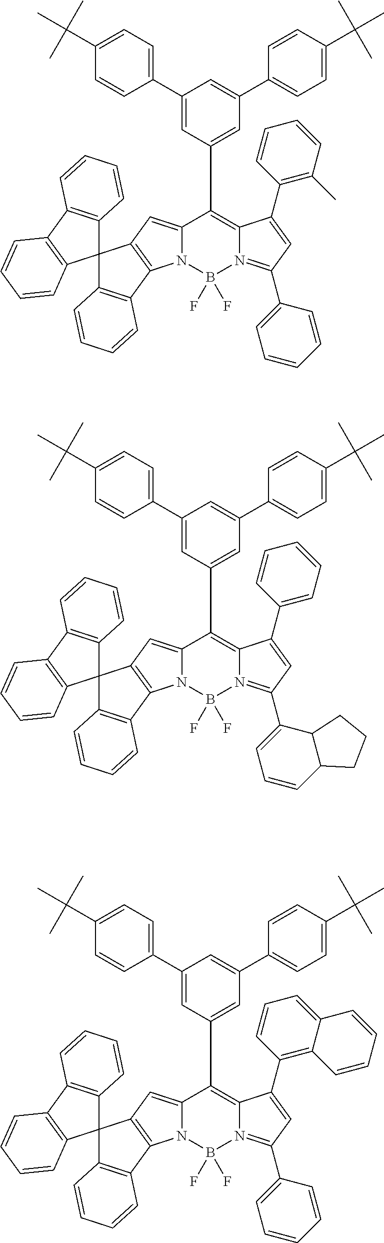

Regarding the synthesis of the pyrromethene-boron complex of the present invention, the compound of the general formula (1) can be synthesized by referring to the methods described in J. Org. Chem., Vol. 64, No. 21, pp. 7813-7819 (1999) and Angew. Chem., Int. Ed. Engl., vol. 36, pp. 1333-1335 (1997), for example. The method includes, for example, a method of heating compounds of the following general formulas (5) and (6) in 1,2-dichloroethane in the presence of phosphorus oxychloride, followed by reaction with a compound of the following general formula (7) in 1,2-dichloroethane in the presence of triethylamine, thereby obtaining a compound of the general formula (1), but the pyrromethene-boron complex of the present invention is not limited thereto. In the formulas, R¹ to R⁹ are the same as described above. J is halogen.

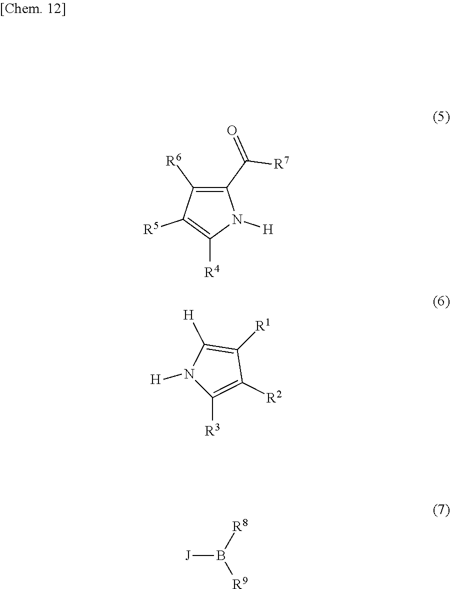

Further, when introducing an aryl group or a heteroaryl group, examples of the method include a method in which a carbon-carbon bond is formed by a coupling reaction between a halogenated derivative and a boronic acid or an esterified derivative of boronic acid, but the pyrromethene-boron complex of the present invention is not limited thereto. Similarly, when introducing an amino group or a carbazolyl group, examples of the method include a method in which a carbon-nitrogen bond is formed by a coupling reaction between a halogenated derivative and an amine or a carbazole derivative in the presence of a metal catalyst such as palladium, but the pyrromethene-boron complex of the present invention is not limited thereto.

In addition, the pyrromethene-boron complex of the present invention is preferably observed to emit light having a peak wavelength in the range of 580 nm to 750 nm when excitation light is used. Hereinafter, the emission light observed to have a peak wavelength in the range of 580 nm to 750 nm may be referred to as “red emission”. In general, the higher the energy of the excitation light is, the more likely a luminescent material will decompose. However, the excitation energy of the excitation light in the wavelength range of 430 nm to 500 nm is relatively small. Thus, decomposition of a luminescent material is prevented, and red emission with high color purity is obtained. Examples of the method of measuring the fluorescence spectrum include a method in which a compound is dissolved in an organic solvent such as toluene and excited with an excitation light having a wavelength in the range of 430 nm to 500 nm to measure the fluorescence spectrum of the compound.

### (Color Conversion Composition)

The color conversion composition according to the embodiment of the present invention (hereinafter sometimes abbreviated as the color conversion composition of the present invention) will be described in detail. Preferably, a color conversion composition of the present invention converts an incident light from a light emitter, such as a light source, into a light having a wavelength longer than that of the incident light, and preferably includes a pyrromethene-boron complex of the present invention as described above and a binder resin as described below.

The color conversion composition of the present invention may appropriately contain, in addition to a pyrromethene-boron complex of the present invention, other compounds as needed. For example, the color conversion composition may contain an assist dopant such as rubrene to further increase the energy transfer efficiency from excitation light to the pyrromethene-boron complex of the present invention. Additionally, in cases where the pyrromethene-boron complex of the present invention is expected to emit different colors of luminescent light in addition to the original color of luminescent light, a desired organic luminescent material, for example an organic luminescent material such as a coumarin derivative or a rhodamine derivative, may be added to the color conversion composition. In addition to an organic luminescent material, a combination of known luminescent materials such as inorganic phosphors, fluorescent pigments, fluorescent dyes, and quantum dots may be added to the color conversion composition. Examples of the organic luminescent material other than the pyrromethene-boron complex of the present invention are shown below, but the present invention is not specifically limited thereto.

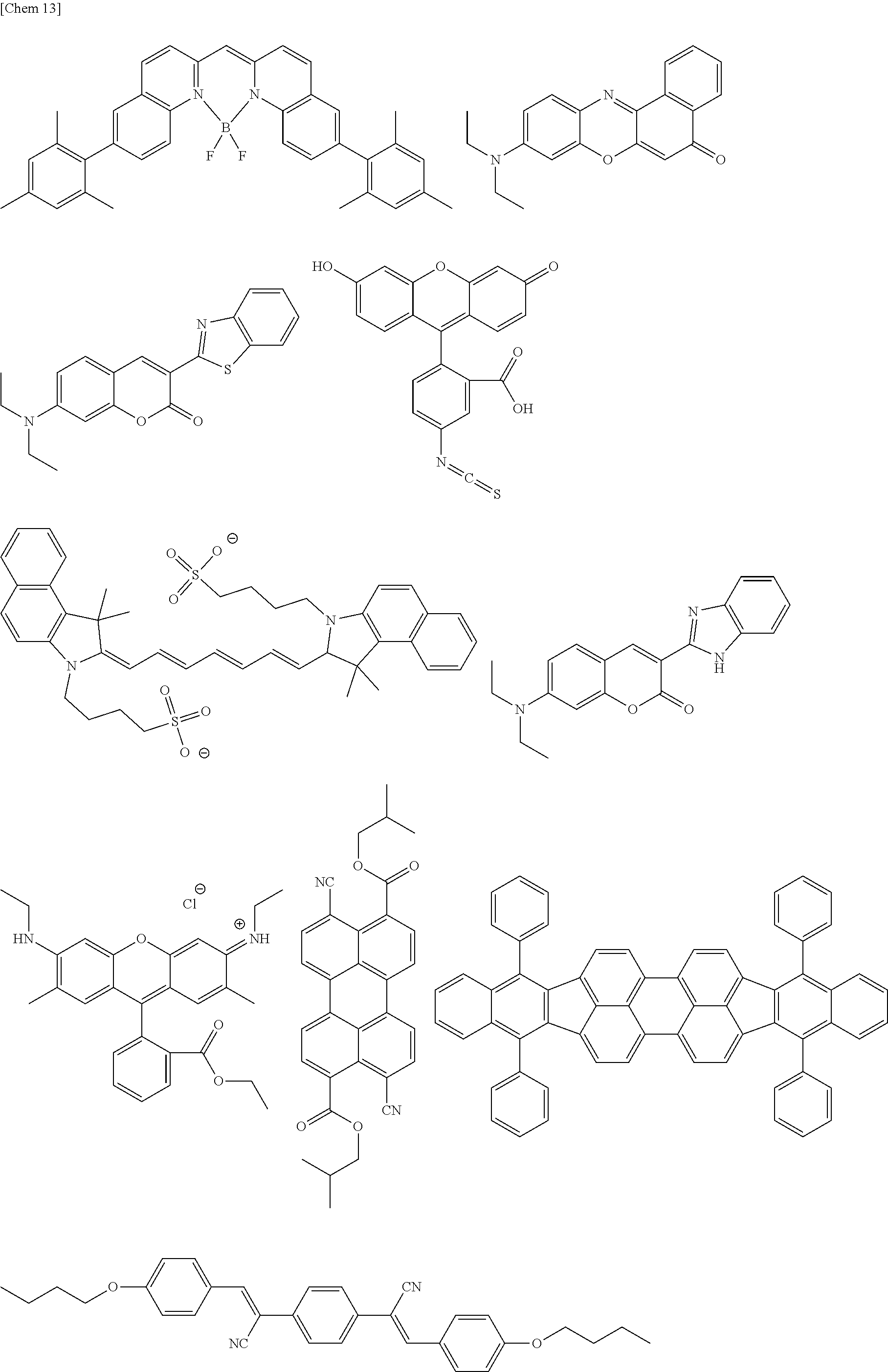

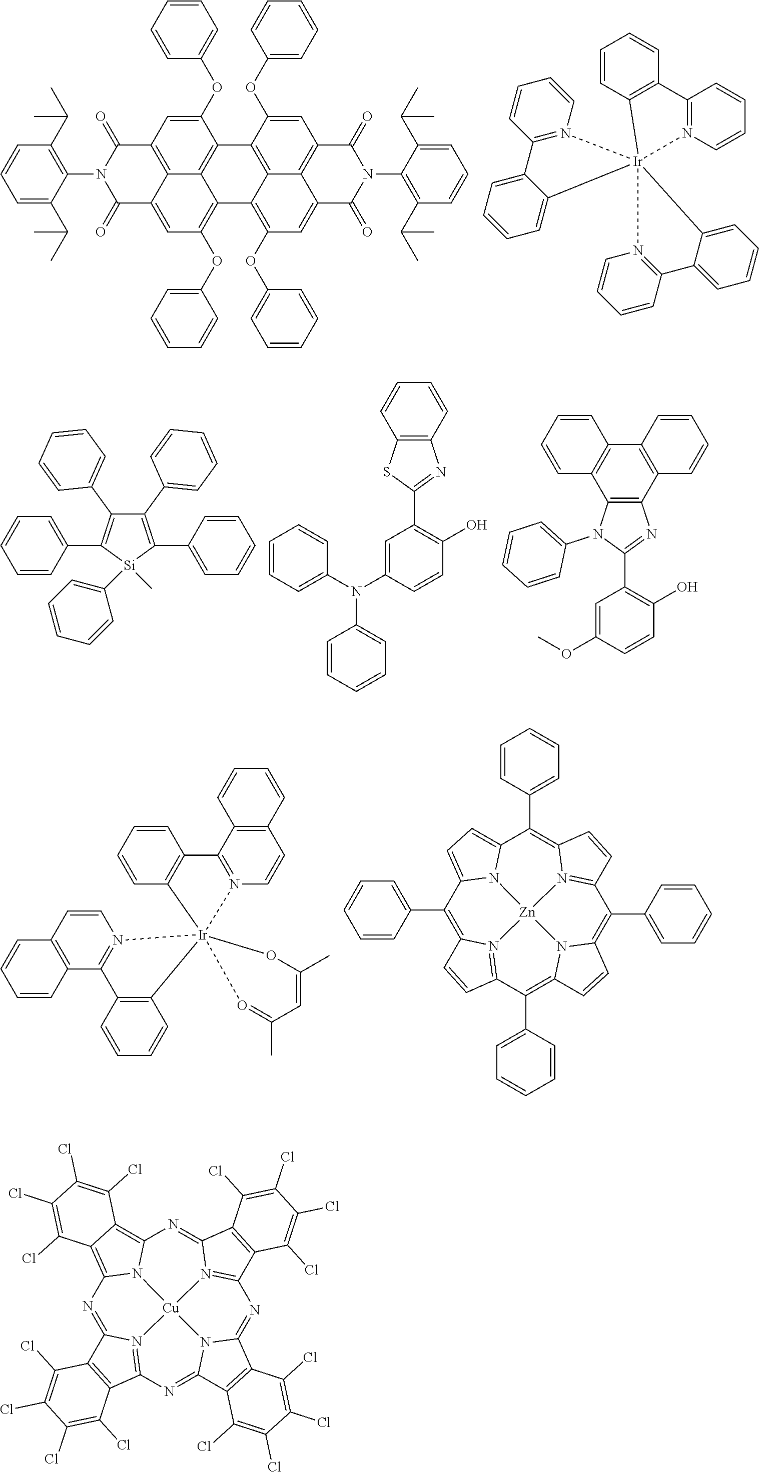

In the present invention, the color conversion composition is preferably observed to emit light (green emission) having a peak wavelength in the range of, for example, 500 nm to less than 580 nm when excitation light is used. In addition, the color conversion composition is preferably observed to emit light (red emission) having a peak wavelength in the range of 580 nm to 750 nm when excitation light is used.

That is, the color conversion composition of the present invention preferably contains the luminescent materials (a) and (b) described below. The luminescent material (a) is observed to emit light having a peak wavelength in the range of 500 nm to less than 580 nm when excitation light is used. The luminescent material (b) that emits light having a peak wavelength observed in the region of 580 nm to 750 nm upon being excited by at least either one of excitation light or light emitted by the luminescent material (a). At least one of these luminescent materials (a) and (b) is preferably the pyrromethene-boron complex of the present invention. Particularly, it is more preferable that the luminescent material (b) is the pyrromethene-boron complex of the present invention. That is, the compound of the general formula (1) mentioned above more preferably emits light observed in a region having a peak wavelength of 580 nm to 750 nm when excitation light is used. Furthermore, it is more preferable to use the excitation light preferably having a wavelength in the range of 430 nm to 500 nm as the excitation light described above.

Since part of the excitation light having a wavelength in the range of 430 nm to 500 nm partially transmits through the color conversion sheet according to the embodiment of the present invention, in the case of using a blue LED having a sharp emission peak, white light having an emission spectrum in a sharp profile in each of blue, green and red colors can be obtained. As a result, particularly in a display device such as display, more vivid colors and a larger color gamut can be efficiently produced. That is, a display device having excellent color reproducibility can be obtained. In the lighting applications, compared with a currently prevailing white LED fabricated by combining a blue LED and a yellow phosphor, the light emission characteristics particularly in the green and red regions are improved, and therefore a preferable white light source with enhanced color rendering properties can be obtained.

As each of the luminescent materials (a) and (b), known materials can be used. For example, a pyrromethene derivative gives a high fluorescence quantum yield and exhibits light emission with high color purity, and is therefore a particularly suitable compound. Among the pyrromethene derivatives, the pyrromethene-boron complex of the present invention has significantly improved durability, and is therefore preferable.

In addition, when the luminescent materials (a) and (b) are both the pyrromethene-boron complex of the present invention, it is possible to achieve both highly efficient emission and high color purity, as well as high durability, which is preferable. In addition, the color conversion composition of the present invention is preferably observed to emit light having a peak wavelength in the range of 580 nm to 750 nm when excitation light is used.

The content of the pyrromethene-boron complex (compound of the general formula (1)) contained in the color conversion composition of the present invention may vary depending on the molar absorption coefficients, luminescence quantum yields, and absorption intensities at the excitation wavelengths of the pyrromethene-boron complex, and the thickness and transmittance of a color conversion sheet produced and are typically 1.0×10⁻⁴ part by mass to 30 parts by mass relative to 100 parts by mass of the binder resin. The content of the pyrromethene-boron complex is more preferably 1.0×10⁻³ part by mass to 10 parts by mass, particularly preferably 1.0×10⁻² part by mass to 5 parts by mass, relative to 100 parts by mass of the binder resin.

### (Binder Resin)

The color conversion composition of the present invention may preferably contain a binder resin, in addition to the above-mentioned pyrromethene-boron complex of the present invention. The binder resin is preferably a material that forms a continuous phase and has excellent formability, processability, transparency, heat resistance, and the like. The binder resin may be, for example, a photocurable resist material having a reactive vinyl group, such as an acrylic, methacrylic, poly(vinyl cinnamate)-based, polyimide-based, or cyclic rubber-based resin, an epoxy resin, a silicone resin (including a cured (crosslinked) organopolysiloxane such as silicone rubber or silicone gel), a urea resin, a fluororesin, a polycarbonate resin, an acrylic resin, a methacryl resin, a polyimide resin, a cycloolefin resin, a polyethylene terephthalate resin, a polypropylene resin, a polystyrene resin, a urethane resin, a melamine resin, a polyvinyl resin, a polyamide resin, a phenol resin, a polyvinyl alcohol resin, a cellulose resin, an aliphatic ester resin, an aromatic ester resin, an aliphatic polyolefin resin, an aromatic polyolefin resin, a hydrogenated styrene-based resin, a resin having a fluorene skeleton in the repeating unit, or a copolymer thereof. The color conversion composition of the present invention may contain two or more of them as the binder resin.

Among these resins, an epoxy resin, a silicone resin, an acrylic resin, or an ester resin is preferably used in view of transparency, and an acrylic resin or an ester resin is more preferably used in view of heat resistance.

These resins can be obtained, for example, by a method comprising copolymerizing monomers materials in the presence of a polymerization initiator. A commercially available binder resin can also be used.

Among the binder resins mentioned above, for example, the silicone resin may be either a thermosetting silicone resin or a thermoplastic silicone resin. Thermosetting silicone resins are cured at a normal temperature or a temperature from 50 to 200° C., and have excellent transparency, heat resistance, and adhesiveness. The thermosetting silicone resin used may also be commercially available, for example, a silicone sealant for use in general LED. Specific examples thereof include OE-6630A/B and OE-6336A/B produced by DuPont Toray Specialty Materials K.K., and SCR-1012A/B and SCR-1016A/B produced by Shin-Etsu Chemical Co., Ltd. The thermoplastic silicone resin may be commercially available, such as RSN series such as RSN-0805 and RSN-0217 produced by DuPont Toray Specialty Materials K.K.

### (Other Component)

The color conversion composition of the present invention may contain, along with the above-mentioned compound of the general formula (1) and a binder resin, other components (additives) such as a light stabilizer, an antioxidant, a processing and heat stabilizer, a light fastness stabilizer such as an ultraviolet absorber, silicone microparticles, and a silane coupling agent.

Examples of the light stabilizer include tertiary amines, catechol derivatives, and lanthanoid compounds. The color conversion composition of the present invention may contain two or more of them as the light stabilizer.

Examples of the antioxidants include phenol antioxidants such as 2,6-di-tert-butyl-p-cresol and 2,6-di-tert-butyl-4-ethylphenol. The color conversion composition of the present invention may contain two or more of them as the antioxidant.

Examples of the processing and heat stabilizers include phosphorus-based stabilizers such as tributyl phosphite, tricyclohexyl phosphite, triethylphosphine, and diphenylbutylphosphine. The color conversion composition of the present invention may contain two or more of them as the processing and heat stabilizer.

Examples of the light fastness stabilizer include benzotriazoles such as 2-(5-methyl-2-hydroxyphenyl)benzotriazole, and 2-[2-hydroxy-3,5-bis(α,α-dimethylbenzyl)phenyl]-2H-benzotriazole. The color conversion composition of the present invention may contain two or more of them as the light fastness stabilizer.

The contents of the additives in the color conversion composition of the present invention can also be set depending on the molar extinction coefficient, fluorescence quantum yield, and absorption intensity at the excitation wavelength of the compound of the general formula (1), and the thickness and transmittance of the color conversion sheet formed. The contents of these additives are preferably 1.0×10⁻³ part by weight or more and 30 parts by weight or less, more preferably 1.0×10⁻² part by weight or more and 15 parts by weight or less, particularly preferably 1.0×10⁻¹ part by weight or more and 10 parts by weight or less, relative to 100 parts by weight of the binder resin.

### (Solvent)

The color conversion composition of the present invention may further contain a solvent, in addition to the compound of the general formula (1) and binder resin described above. Preferably, the solvent can adjust the viscosity of a resin in a flowing state, and does not excessively affect the emission from a luminescent substance and the durability. Examples of such a solvent include toluene, methyl ethyl ketone, methyl isobutyl ketone, hexane, acetone, terpineol, texanol, methyl cellosolve, butyl carbitol, butyl carbitol acetate, and propylene glycol monomethyl ether acetate. The color conversion composition of the present invention may contain two or more of them as the solvent. Especially among these solvents, toluene does not affect deterioration of the compound of the general formula (1), leaves less residual solvent after drying and therefore, is suitably used.

### (Method of Producing Color Conversion Composition)

One example of the method of producing the color conversion composition according to the embodiment of the present invention is described below. In this production method, predetermined amounts of, for example, the above-mentioned compound of the general formula (1), a binder resin, and additives and a solvent, as needed, are mixed. These components can be mixed so that a predetermined composition is achieved, and then homogeneously mixed or kneaded using a stirrer/kneader to obtain a color conversion composition of the present invention. Examples of the stirrer/kneader include homogenizers, rotation-revolution stirrers, three-roll mills, ball mills, planetary ball mills, and beads mills. After mixing or dispersing, or in the process of mixing or dispersing, defoaming is also preferably performed under a vacuum or reduced-pressure condition. In addition, a specific component may be added in advance, or a treatment such as aging may be performed. The solvent can be removed by an evaporator to achieve a desired solid concentration.

### (Color Conversion Sheet)

The color conversion sheet according to the embodiment of the present invention (hereinafter sometimes abbreviated as color conversion sheet of the present invention) includes a color conversion layer composed of the above-mentioned color conversion composition of the present invention or a cured product thereof. In the present invention, the color conversion sheet is not limited in its constitution as long as it includes the above-described color conversion layer. For example, a color conversion sheet may include, in addition to the above-described color conversion layer, a substrate layer and a barrier film as necessary, and may include two or more of these layers.

From the viewpoint of enhancing heat resistance of the color conversion sheet, the film thickness of the color conversion sheet of the present invention is preferably 200 μm or less, more preferably 100 μm or less, still more preferably 50 μm or less. The film thickness of a color conversion sheet of the present invention is a film thickness (a mean film thickness) measured by the thickness measurement method A based on mechanical scanning in JIS K7130 (1999) “Plastics-Film and sheeting-Determination of thickness”. When the film thickness (thickness) of the color conversion sheet is 50 μm or more, the toughness of the color conversion sheet can be improved. When the film thickness of the color conversion sheet is 200 μm or less, cracking of the color conversion sheet can be prevented.

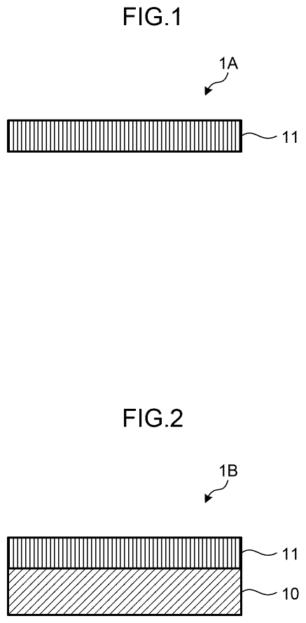

Representative structural examples of the color conversion sheet of the present invention include the following four examples. FIG. 1 is a schematic cross-sectional view illustrating the first example of the color conversion sheet according to the embodiment of the present invention. As shown in FIG. 1, the color conversion sheet 1A of the first example is a monolayer sheet composed of a color conversion layer 11. The color conversion layer 11 is a layer composed of a cured product of the color conversion composition as described above.

FIG. 2 is a schematic cross-sectional view illustrating the second example of the color conversion sheet according to the embodiment of the present invention. As shown in FIG. 2, the color conversion sheet 1B of this second example is a laminate of a substrate layer 10 and a color conversion layer 11. In the structural example of the color conversion sheet 1B, the color conversion layer 11 is laminated on the substrate layer 10.

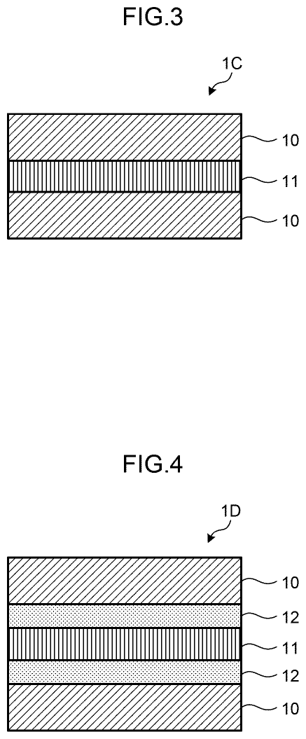

FIG. 3 is a schematic cross-sectional view illustrating the third example of the color conversion sheet according to the embodiment of the present invention. As shown in FIG. 3, the color conversion sheet 1C of the third example is a laminate of a plurality of substrate layers 10 and the color conversion layer 11. In the structural example of this color conversion sheet 1C, the color conversion layer 11 is sandwiched between the plurality of substrate layers 10.

FIG. 4 is a schematic cross-sectional view illustrating the fourth example of the color conversion sheet according to the embodiment of the present invention. As shown in FIG. 4, the color conversion sheet 1D of the fourth example is a laminate composed of a plurality of substrate layers 10, a color conversion layer 11, and a plurality of barrier films 12. In the structural example of the color conversion sheet 1D, the color conversion layer 11 is sandwiched between the plurality of barrier films 12, and the laminate composed of the color conversion layer 11 and the plurality of barrier films 12 is further sandwiched between the plurality of substrate layers 10. That is, the color conversion sheet 1D may include the barrier films 12, as shown in FIG. 4, to prevent the color conversion layer 11 from being deteriorated by oxygen, water moisture, or heat.

### (Substrate Layer)

Examples of the material constituting the substrate layer (for example, the substrate layer 10 shown in FIG. 2 to FIG. 4) include glass and a resin film. The resin film is preferably, for example, a plastic film such as polyethylene terephthalate (PET), polyphenylene sulfide, polycarbonate, polypropylene, or polyimide. The surface of the substrate layer can be pre-treated with mold release to facilitate release of the film.

The lower limit of the thickness of the substrate layer is preferably 25 μm or more, and more preferably 38 μm or more. Additionally, the upper limit of the thickness of the substrate layer is preferably 5,000 μm or less, and more preferably 3,000 μm or less.

### (Color Conversion Layer)

The color conversion layer (for example, color conversion layer 11 shown in FIG. 1 to FIG. 4) is a layer composed of a color conversion composition as described above or a cured product thereof. When the color conversion sheet of the present invention has a plurality of color conversion layers, the plurality of color conversion layers may be laminated directly or via an intermediate layer such as an adhesive layer. The thickness of the color conversion layer is preferably from 30 to 100 μm.

### (Barrier Film)

The barrier film (for example, barrier film 12 shown in FIG. 4) preferably prevents penetration of oxygen, water, heat, and the like into the color conversion layer. The color conversion sheet of the present invention may contain two or more barrier films. The color conversion sheet of the present invention may have barrier films on the both sides of the color conversion layer, as shown in FIG. 4, or may have a barrier film on only one side of the color conversion layer.

In addition, the color conversion sheet of the present invention may further include an auxiliary layer having a function such as anti-reflection function, anti-glare function, anti-reflection and anti-glare function, hard coating function (antifriction function), antistatic function, anti-fouling function, electromagnetic shielding function, infrared cutting function, ultraviolet cutting function, polarization function, or color changing function depending on the functions required for a color conversion sheet.

### (Method of Producing Color Conversion Sheet)

Next, one example of the method of producing the color conversion sheet according to the embodiment of the present invention is described below. In the method of producing the color conversion sheet, the color conversion composition prepared by the method described above is applied to the base material such as a substrate layer or a barrier film, and allowed to dry, thereby to form a color conversion layer. When the binder resin contained in the color conversion composition is a thermosetting resin, the color conversion composition may be applied to a base material, and then thermally cured to form a color conversion layer. When the binder resin contained in the color conversion composition is a photocurable resin, the color conversion composition may be applied to a base material, and then photo-cured to form a color conversion layer.

The color conversion compositions can be applied by means of a reverse roll coater, a blade coater, a slit die coater, a direct gravure coater, an offset gravure coater, a kiss coater, a natural roll coater, an air knife coater, a roll blade coater, a reverse roll blade coater, a two-stream coaters, a rod coater, a wire bar coater, an applicator, a dip coater, a curtain coater, a spin coater, a knife coater, or the like. Among them, in order to achieve film thickness uniformity of the color conversion layer, the composition is preferably applied by means of a slit die coater.

The color conversion layer can be dried using a general heating apparatus such as hot air drier or infrared drier. In this case, the heating temperature is preferably from 60° C. to 200° C., and the heating time is preferably from 2 minutes to 4 hours. It is also possible to perform stepwise thermal curing of the color conversion layer by step-cure or other methods.

When the color conversion layer is formed by thermal curing, the heating apparatus may be, for example, a hot air oven. The heating conditions can be selected depending on the binder resin in the color conversion composition. For example, the heating temperature is preferably from 100° C. to 300° C., and the heating time is preferably from 1 minute to 2 hours.

When the color conversion layer is formed by photo-curing, the color conversion layer is preferably irradiated with high-energy light such as ultraviolet rays. The photoirradiation conditions can be selected depending on the binder resin in the color conversion composition. For example, the wavelength of the irradiated light is preferably from 200 nm to 500 nm, and the amount of irradiation of the light is preferably from 10 mJ/cm² to 10 J/cm².

After preparing the color conversion layer, the substrate layer may be changed, as necessary. In this case, simple methods include, for example, methods of re-laminating the substrate by using a hot plate, and methods using a vacuum laminator or a dry film laminator.

Examples of the evaluation of the fluorescence quantum yield of the color conversion sheet include a method in which the color conversion sheet prepared is cut into 8 mm×8 mm samples, and the color conversion sheet is irradiated with an excitation light using an absolute fluorescence quantum yield meter to excite the luminescent material in the color conversion layer of the color conversion sheet for measurement.

### (Color Conversion Substrate)

The color conversion substrate according to the embodiment of the present invention (hereinafter sometimes abbreviated as color conversion substrate of the present invention) is a substrate including a plurality of color conversion layers on a transparent substrate. In the color conversion substrate, each of the plurality of color conversion layers is a layer composed of the color conversion composition of the present invention mentioned above or a cured product thereof. That is, each of the plurality of color conversion layers is a color conversion layer containing at least the above-mentioned pyrromethene-boron complex of the present invention.

In the color conversion substrate of the present invention, the plurality of color conversion layers preferably include a red color conversion layer and a green color conversion layer. The red color conversion layer is formed of a phosphor material that absorbs at least a blue light and emits a red light. The green color conversion layer is formed of a phosphor material that absorbs at least a blue light and emits a green light. In the color conversion substrate of the present invention, partition walls may be formed. Each of the plurality of color conversion layers may be placed between the partition walls (in a recess).

In a method of using the color conversion substrate of the present invention, an excitation light may be irradiated from the transparent substrate side and the light emission may be visually observed from the side opposite to the transparent substrate, or an excitation light may be irradiated from the color conversion layer side and the light emission may be visually observed from the transparent substrate side.

The quantum yield of the color conversion layer described above is usually 0.5 or more, preferably 0.7 or more, more preferably 0.8 or more, and especially preferably 0.9 or more when the color conversion substrate is irradiated with a blue light having a peak wavelength of 440 nm to 460 nm.

### (Excitation Light)

As for types of the excitation light, any type of excitation light can be used as long as it emits a light in the wavelength region where the luminescent material such as the pyrromethene-boron complex of the present invention can absorb light. For example, excitation light from any light source such as that from a fluorescent light source, such as a hot cathode tube, cold cathode tube, or inorganic electroluminescence (EL), an organic EL element light source, an LED light source, an incandescent light source, or sunlight can be used in principle. In particular, a light from an LED light source is a suitable excitation light. In display devices or lighting devices, a light from a blue LED light source having an excitation light in the wavelength range of 430 nm to 500 nm is a more suitable excitation light from the viewpoint that the color purity of blue light can be enhanced.

The excitation light can have one emission peak or two or more emission peaks, but excitation light with a single emission peak is preferred to increase color purity. It is also possible to use a plurality of excitation light sources having different types of emission peaks in an arbitrary combination.

### (Light Source Unit)

The light source unit according to the embodiment of the present invention (hereinafter sometimes abbreviated as light source unit of the present invention) is configured to include at least a light source and the above-mentioned color conversion sheet or color conversion substrate. The light source serves, for example, as a source of the above-mentioned excitation light. The methods of positioning the light source and the color conversion sheet or the color conversion substrate are not particularly limited, and a constitution in which the light source may be in close contact with the color conversion sheet or the color conversion substrate, or a remote phosphor system in which the light source is separated from the color conversion sheet or the color conversion substrate may be employed. In addition, for the purpose of increasing the color purity, the light source unit of the present invention may employ a constitution further including a color filter.

As mentioned above, the excitation light having a wavelength in the range of 430 nm to 500 nm has a relatively small amount of excitation energy and can prevent a luminescent material such as a pyrromethene-boron complex of the present invention from being decomposed. Therefore, the light source used in the light source unit of the present invention is preferably a light emitting diode having a maximum light emission wavelength in the range of 430 nm to 500 nm. Furthermore, the light source preferably has a maximum light emission wavelength in the range of 440 nm to 470 nm.

### (Display Device, Lighting Device)

The display device according to the embodiment of the present invention includes the above-mentioned color conversion sheet or color conversion substrate of the present invention. For example, in a display device such as a liquid crystal display, a light source unit having the above-mentioned light source, color conversion sheet, and color conversion substrate etc. is used as a backlight unit. In addition, a lighting device according to the embodiment of the present invention includes the above-mentioned color conversion sheet or color conversion substrate. For example, this lighting device is configured as a light source unit to emit a white light by combining a blue LED light source with a color conversion sheet or a color conversion substrate that converts a blue light from this blue LED light source into a light having a longer wavelength.

### EXAMPLES

The present invention is described below by referring to Examples, but the present invention is not limited by these Examples. Compounds R-1 to R-13 and R-101 to R-104 in the following Examples and Comparative Examples are compounds shown below.

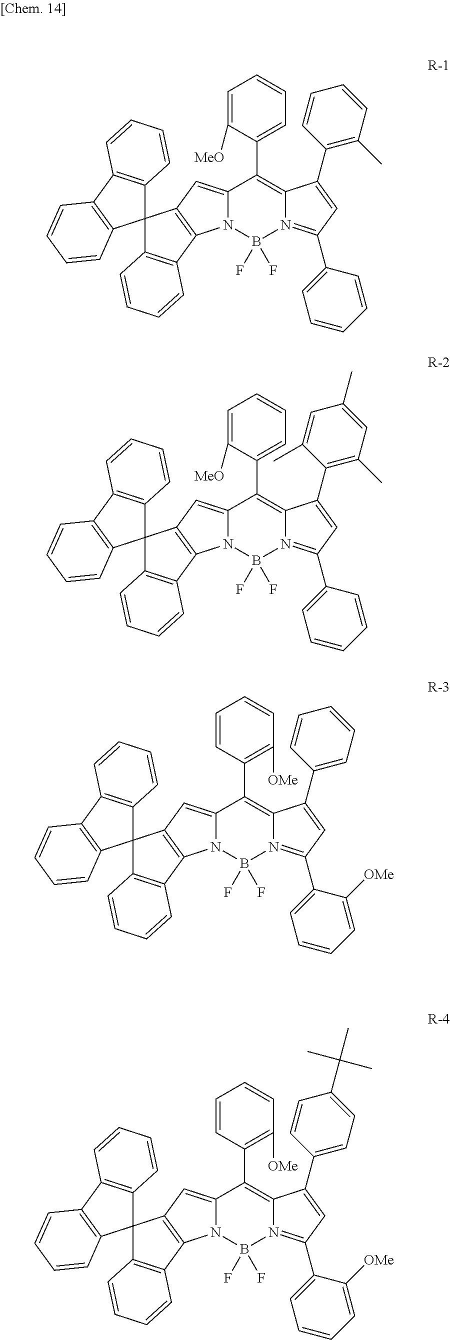

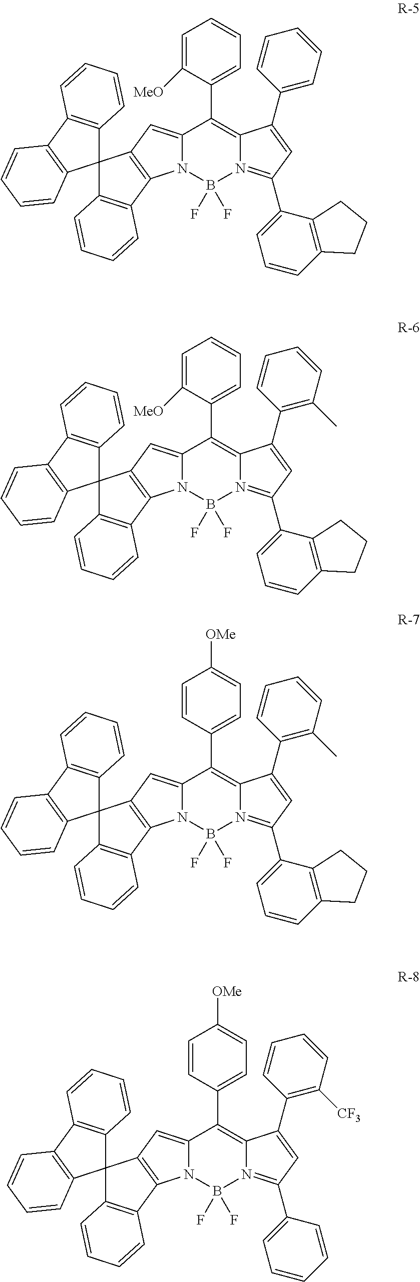

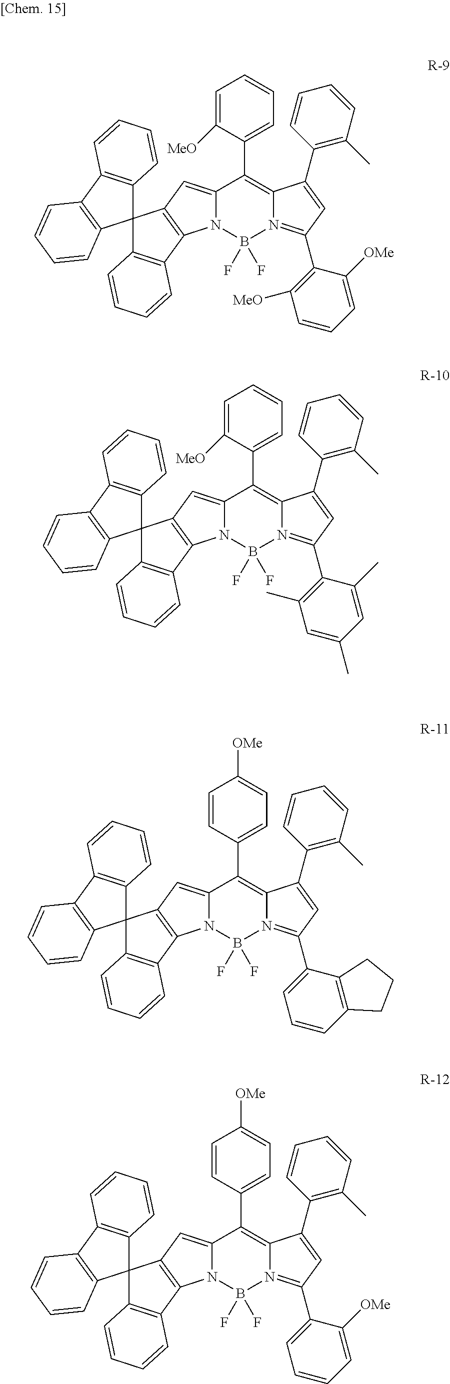

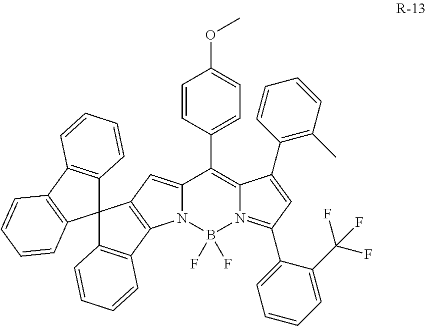

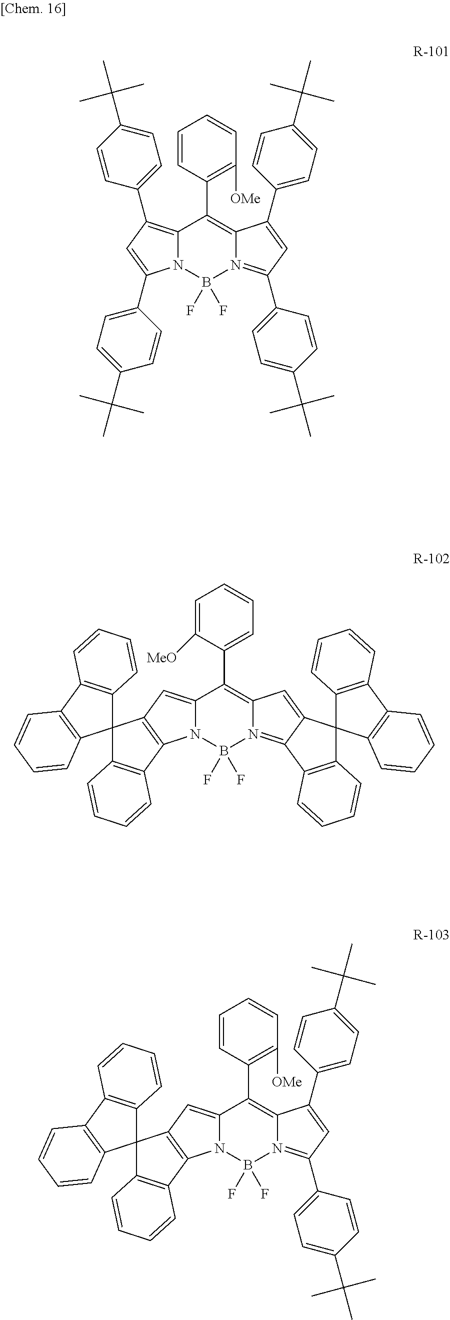

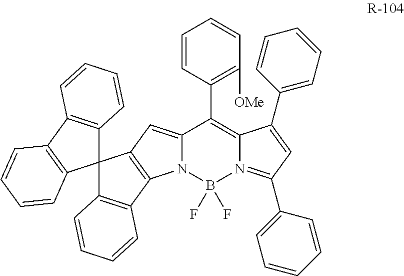

The measurement method and the evaluation method used in Examples and Comparative Examples are described below.

(Measurement of ¹H-NMR) 1H-NMR of the compound was measured with a deuterated chloroform solution by using superconducting FTNMR EX-270 (manufactured by JEOL Ltd.).

### (Measurement of Ultraviolet-Visible Absorption Spectrum of Compound)

When the ultraviolet-visible absorption spectrum of a compound was measured, the compound was dissolved in toluene to a concentration of 1×10⁻⁶ mol/L and then the ultraviolet-visible absorption spectrum was measured at the wavelength of 300 nm to 800 nm using an U-3010 UV spectrophotometer (manufactured by Hitachi, Ltd.) to obtain a peak wavelength of the ultraviolet-visible absorption spectrum (hereinafter also referred to as absorption peak wavelength). The results for measurement of absorption peak wavelength are as shown in Table 1 below. The obtained absorption peak wavelength was used as one of the indices for evaluating the half-value width of the emission spectrum and color purity of the compound.

### (Measurement of Fluorescence Spectrum of Compound)

When the fluorescence spectrum of a compound was measured, the compound was dissolved in toluene to a concentration of 1×10⁻⁶ mol/L and then excited at a wavelength of 540 nm to measure the fluorescence spectrum using a Fluoromax-4P fluorescence and phosphorescence spectrophotometer (manufactured by HORIBA, Ltd.) to obtain a peak wavelength of the fluorescence spectrum (hereinafter also referred to as emission peak wavelength). The results for the emission peak wavelength are as shown in Table 1 below. The obtained emission peak wavelength was used as one of the indices for evaluating the half-value width of the emission spectrum and color purity of the compound.

### (Calculation of Stokes Shift of Compound)

The Stokes shift of a compound was calculated from the difference in peak wavelength between the ultraviolet-visible absorption spectrum and the fluorescence spectrum obtained for the compound as described above, that is, the difference between the absorption peak wavelength and the emission peak wavelength. The results for the Stokes shift are as shown in Table 1 below.

### (Measurement of Fluorescence Quantum Yield of Color Conversion Sheet Using Color Conversion Composition)

For the measurement of the fluorescence quantum yield, in each of Examples and each of Comparative Examples, a color conversion sheet prepared using the color conversion composition was cut into 8 mm×8 mm samples, thereby preparing the samples of the color conversion sheet. The prepared samples were excited with an excitation light with a wavelength of 540 nm and analyzed for their fluorescence quantum yields using an absolute fluorescence quantum yield meter Quantaurus-QY manufactured by Hamamatsu Photonics K.K.

### Synthesis Example 1

The method of synthesizing compound R-1 is described in Synthesis Example 1. In this method of synthesis, a mixed solution of 2-phenyl-4-(o-tolyl) pyrrole (2.00 g), 2-methoxybenzoyl chloride (1.05 g), and o-xylene (30 mL) was heated to reflux with stirring for 6 hours under a nitrogen gas stream. Then, after the mixed solution was cooled to room temperature, methanol was added, and the precipitated solid was filtered and vacuum dried to obtain 2-(2-methoxybenzoyl)-3-(o-tolyl)-5-phenylpyrrole (2.48 g).

Then, the mixed solution of 2-(2-methoxybenzoyl)-3-(o-tolyl)-5-phenylpyrrole (2.48 g), spirofluorene indenopyrrole (0.96 g), methanesulfonic anhydride (1.10 g), and degassed toluene (32 mL) obtained as described above was heated at 125° C. for 7 hours under a nitrogen gas flow. After the solution was cooled to room temperature, water (32 mL) was added, and then an organic layer was extracted with toluene (32 mL). The obtained organic layer was washed twice with water (20 mL), magnesium sulfate was added to the organic layer after washing, and the mixture was filtered. The solvent was removed from the obtained filtrate using an evaporator to obtain a residual pyrromethene body. Then, to the mixed solution of the obtained pyrromethene body and toluene (32 mL), diisopropylethylamine (1.62 mL) and a boron trifluoride diethyl ether complex (2.39 mL) were added under a nitrogen gas flow, and the resulting mixture was stirred at 80° C. for 1 hour. Subsequently, water (32 mL) was added to the mixed solution after stirring, and an organic layer was extracted with dichloromethane (32 mL). The obtained organic layer was washed twice with water (20 mL), dried over magnesium sulfate, and then the solvent was removed from the organic layer using an evaporator. The residue in this case was purified by silica gel column chromatography and dried under vacuum to obtain a magenta powder (1.48 g).

The result of ¹H-NMR analysis of the obtained magenta powder was as follows, and the magenta powder obtained above was confirmed to be the compound R-1. Spirofluorene indenopyrrole was synthesized according to the known methods described in Org. Lett., Vol. 12, pp. 296 (2010) and the like.

Compound R-1: ¹H-NMR (CDCl₃ (d=ppm)) δ1.97 (s, 3H), 3.39 (s, 3H), 5.96 (s, 1H), 6.13 (d, 1H), 6.20 (d, 1H), 6.50-6.58 (m, 3H), 6.63 (t, 1H), 6.70 (d, 1H), 6.84-7.00 (m, 5H), 7.09-7.20 (m, 3H), 7.29-7.40 (m, 3H), 7.49-7.58 (m, 3H), 7.75 (t, 2H), 8.06 (t, 2H), 8.30 (d, 1H)

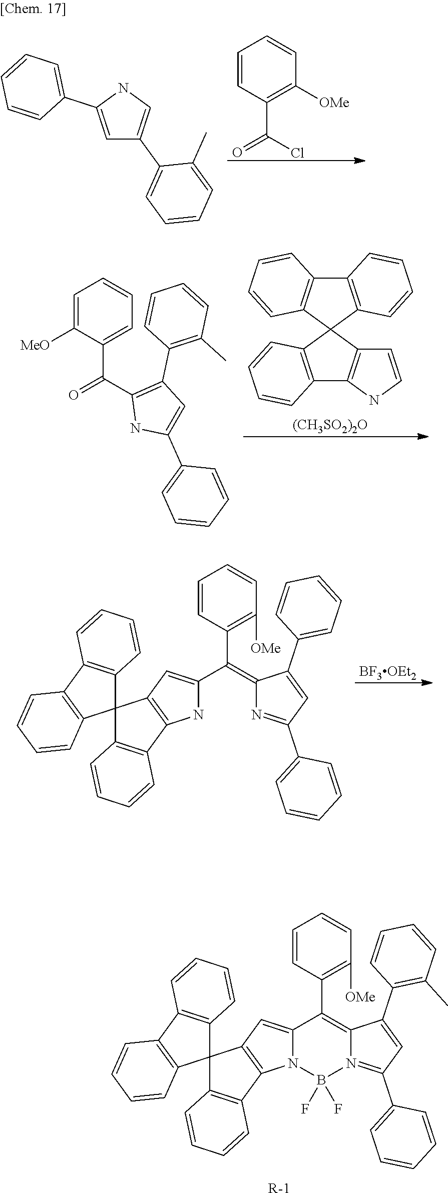

Compounds other than those described above can be easily synthesized by modifying the various raw materials such as pyrrole or benzoyl chloride.

### Example 1

In Example 1, a polymethyl methacrylate resin “BR-88” (manufactured by Mitsubishi Chemical Corporation) was used as a binder resin, and 1.1 parts by weight of compound R-1 as a luminescent material, and 200 parts by weight of ethyl acetate as a solvent were mixed with 100 parts by weight of the polymethyl methacrylate resin. The resulting mixture was then stirred and defoamed at 1,000 rpm for 20 minutes using a planetary stirring and defoaming mixer “MAZERUSTAR KK-400” (manufactured by Kurabo Industries Ltd.) to obtain a color conversion composition (red color conversion composition) as a resin liquid for preparation of a sheet.

Next, the red color conversion composition obtained as described above was applied on a polyester film “LUMIRROR®” U48 (manufactured by Toray Industries, Inc.; thickness: 50 μm) using a slit die coater, and heated and dried at 140° C. for 20 minutes thereby to form a red color conversion sheet having a mean film thickness of 18 μm. The fluorescence quantum yield of this red color conversion sheet was measured to be 90%. The evaluation results for Example 1 are summarized in Table 1, along with the measurement results for spectra and the like of Compound R-1.

### Examples 2 to 13 and Comparative Examples 1 to 4

In each of Examples 2 to 13 and Comparative Examples 1 to 4, color conversion sheets were produced and evaluated in the same manner as in Example 1, except that the compounds listed in Table 1 were used as luminescent materials. The evaluation results for Examples 2 to 13 and Comparative Examples 1 to 4 are summarized in Table 1, along with the measurement results for spectra and the like of the compound.

TABLE 1

| | | Absorp- | | | | |
|---|---|---|---|---|---|---|
| | | tion | Emission | | | Fluores- |
| | | peak | peak | Half- | | cence |
| | | wave- | wave- | value | Stokes | quantum |
| | Com- | length | length | width | shift | yield |
| | pound | (nm) | (nm) | (nm) | (nm) | (%) |
| Example 1 | R-1 | 601 | 623 | 35 | 22 | 90 |
| Example 2 | R-2 | 601 | 622 | 33 | 21 | 92 |
| Example 3 | R-3 | 590 | 629 | 39 | 39 | 84 |
| Example 4 | R-4 | 590 | 626 | 39 | 36 | 85 |
| Example 5 | R-5 | 590 | 623 | 38 | 33 | 80 |
| Example 6 | R-6 | 587 | 620 | 38 | 33 | 88 |
| Example 7 | R-7 | 597 | 618 | 33 | 21 | 90 |
| Example 8 | R-8 | 597 | 623 | 30 | 26 | 95 |
| Example 9 | R-9 | 601 | 622 | 35 | 21 | 90 |
| Example 10 | R-10 | 601 | 622 | 35 | 21 | 91 |
| Example 11 | R-11 | 585 | 617 | 38 | 32 | 88 |
| Example 12 | R-12 | 598 | 620 | 33 | 22 | 92 |
| Example 13 | R-13 | 597 | 623 | 31 | 26 | 95 |
| Comparative | R-101 | 576 | 614 | 43 | 38 | 76 |
| Example 1 | | | | | | |
| Comparative | R-102 | 586 | 613 | 26 | 9 | 76 |
| Example 2 | | | | | | |
| Comparative | R-103 | 610 | 632 | 37 | 22 | 70 |
| Example 3 | | | | | | |
| Comparative | R-104 | 604 | 627 | 36 | 23 | 67 |
| Example 4 | | | | | | |

Comparison of Examples 1 to 13 to Comparative Example 1 demonstrates that introduction of a fused ring structure into a pyrromethene skeleton makes it possible to decrease half-value width and obtain light emission with high color purity. Comparison of Examples 1 to 13 to Comparative Example 2 demonstrates that those in which fused ring structure in the pyrromethene skeleton is a single-sided fused ring have a larger Stokes shift than those in which fused ring structure in the pyrromethene skeleton is a double-sided fused ring. Comparison of Examples 1 to 13 to Comparative Examples 3, 4 demonstrates that when R¹ and R³ in the pyrromethene-boron complex that is a luminescent material is aryl groups which are different from each other, the fluorescence quantum yield of the color conversion sheet is improved.

In addition, as compared among Examples 1 to 13, when R¹ and R³ are phenyl groups which are different from each other, the fluorescence quantum yield is higher, and when R¹ is a phenyl group having a substituent in the ortho position, the fluorescence quantum yield is higher. Furthermore, among those in which R¹ is a phenyl group having a substituent in the ortho position, those in which the substituent is an electron withdrawing group have a larger Stokes shift.

### INDUSTRIAL APPLICABILITY

As described above, the pyrromethene-boron complex, color conversion composition, color conversion sheet, color conversion substrate, light source unit, display device, and lighting device according to the present invention are suitable for achieving both high color purity and high fluorescence quantum yield.

### REFERENCE SIGNS LIST

1A, 1B, 1C, 1D color conversion sheet
10 substrate layer
11 color conversion layer
12 barrier film

1. A pyrromethene-boron complex which is a compound of the following general formula (1): 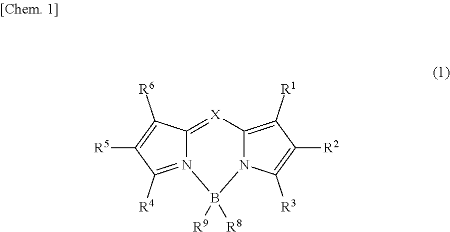
(wherein in the general formula (1), X is C—R⁷ or N; R¹ and R³ are aryl groups which are different from each other; each of R² and R⁴ to R⁹, which may be the same as or different from one another, is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group, provided that one of two pairs: R⁴ and R⁵, and R⁵ and R⁶, has a ring structure of any one of the following general formulas (2A) to (2D): 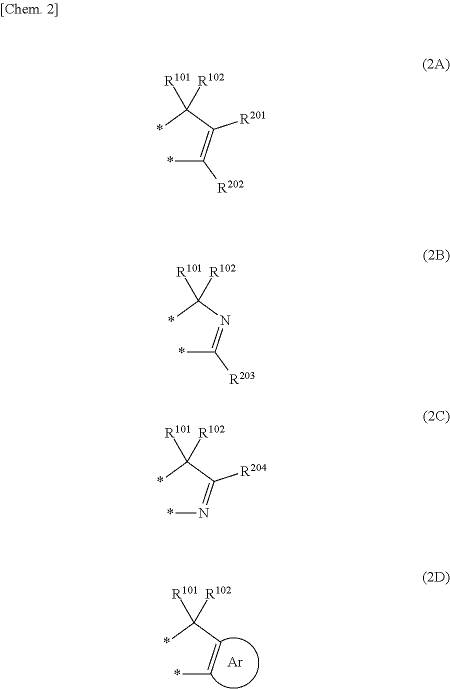
(wherein in the general formulas (2A) to (2D), R¹⁰¹, R¹⁰², and R²⁰¹ to R²⁰⁴ are the same as R², and R⁴ to R⁹ in said general formula (1); Ar is a substituted or unsubstituted aromatic hydrocarbon ring, or a substituted or unsubstituted aromatic heterocycle; R¹⁰¹ and R¹⁰² may form a ring; and the symbol * indicates a connection with the pyrromethene skeleton)).

2. The pyrromethene-boron complex according to claim 1, wherein the compound of the general formula (1) is a compound of any one of the following general formulas (3A) to (3D): 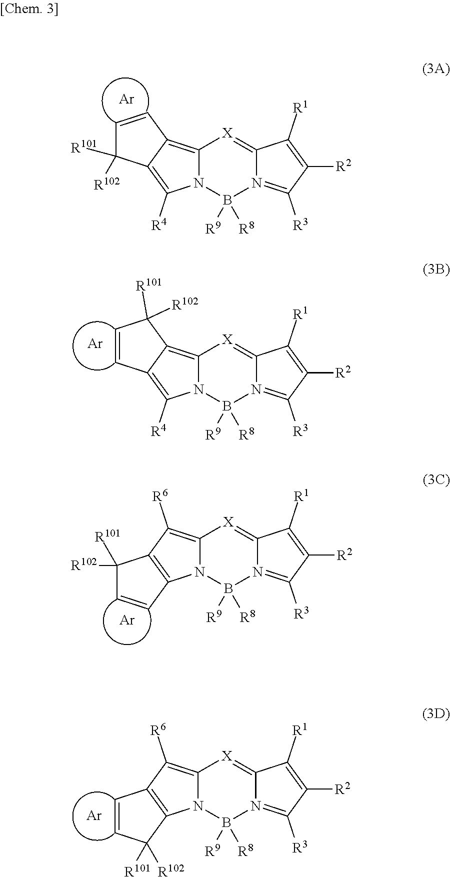
(wherein in the general formulas (3A) to (3D), R¹⁰¹ and R¹⁰² are the same as R², and R⁴ to R⁹ in said general formula (1); Ar is a substituted or unsubstituted aromatic hydrocarbon ring, or a substituted or unsubstituted aromatic heterocycle; and R¹⁰¹ and R¹⁰² may form a ring).

3. The pyrromethene-boron complex according to claim 1, wherein the Ar is a substituted or unsubstituted benzene ring.

4. The pyrromethene-boron complex according to claim 1, wherein in the general formula (1), R¹ and R³ are substituted or unsubstituted phenyl groups which are different from each other.

5. The pyrromethene-boron complex according to claim 1, wherein in the general formula (1), R¹ is a phenyl group having a substituent in the ortho position.

6. The pyrromethene-boron complex according to claim 1, wherein in the general formulas (1), and (2A) to (2D), at least one of R¹ to R³, R¹⁰¹, R¹⁰², R²⁰¹ to R²⁰⁴, and Ar is a group containing an electron withdrawing group.

7. The pyrromethene-boron complex according to claim 1, wherein in the general formula (1), at least one of R¹ to R³ is a group containing an electron withdrawing group.

8. The pyrromethene-boron complex according to claim 6, wherein the electron withdrawing group is fluorine, a fluorine-containing aryl group, a fluorine-containing heteroaryl group, a fluorine-containing alkyl group, a substituted or unsubstituted acyl group, a substituted or unsubstituted ester group, a substituted or unsubstituted amide group, a substituted or unsubstituted sulfonyl group, or a cyano group.

9. The pyrromethene-boron complex according to claim 1, wherein in the general formula (1), X is C—R⁷, and R⁷ is a group of the following general formula (4): 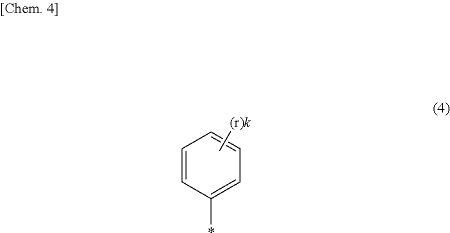
(wherein in the general formula (4), r is selected from the group consisting of a hydrogen atom, an alkyl group, a cycloalkyl group, a heterocyclic group, an alkenyl group, a cycloalkenyl group, an alkynyl group, a hydroxyl group, a thiol group, an alkoxy group, an alkylthio group, an aryl ether group, an aryl thioether group, an aryl group, a heteroaryl group, halogen, a cyano group, an aldehyde group, a carbonyl group, a carboxyl group, an oxycarbonyl group, a carbamoyl group, an amino group, a nitro group, a silyl group, a siloxanyl group, a boryl group, and a phosphine oxide group; k is an integer of 1 to 3; and when k is 2 or more, r may be the same as or different from one another.)

10. The pyrromethene-boron complex according to claim 1, wherein the compound of the general formula (1) emits light observed in a region having a peak wavelength of 580 nm to 750 nm when excitation light is used.

11. A color conversion composition that converts incident light into a light with a wavelength longer than that of the incident light, comprising:
the pyrromethene-boron complex according to claim 1; and
a binder resin.

12. A color conversion sheet comprising a color conversion layer composed of the color conversion composition according to claim 11 or a cured product thereof.

13. A color conversion substrate comprising a plurality of color conversion layers on a transparent substrate, wherein the plurality of color conversion layers are composed of the color conversion composition according to claim 11 or a cured product thereof.

14. A light source unit comprising:
a light source, and
the color conversion sheet according to claim 12.

15. The light source unit according to claim 14, wherein the light source is a light-emitting diode having a maximum light emission in the wavelength range of 430 nm to 500 nm.

16. A display device comprising the color conversion sheet according to claim 12.

17. A lighting device comprising the color conversion sheet according to claim 12.

18. A light source unit comprising:
a light source, and
the color conversion substrate according to claim 13.

19. A display device comprising the color conversion substrate according to claim 13.

20. A lighting device comprising the color conversion substrate according to claim 13.
